(19) United States
(12) Patent Application Publication
(10) Pub. No.: US 2017/0338252 A1
(43) Pub. Date: Nov. 23, 2017

(54) DISPLAY DEVICE

(71) Applicant: InnoLux Corporation, Miao-Li County (TW)

(72) Inventors: Kuan-Feng LEE, Miao-Li County (TW); Chandra LIUS, Miao-Li County (TW); Nai-Fang HSU, Miao-Li County (TW)

(21) Appl. No.: 15/480,458

(22) Filed: Apr. 6, 2017

Related U.S. Application Data
(60) Provisional application No. 62/337,384, filed on May 17, 2016.
(60) Provisional application No. 62/358,177, filed on Jul. 5, 2016.

(30) Foreign Application Priority Data
Dec. 1, 2016 (CN) 201611089421.1

(51) Int. Cl. H01L 27/12; H01L 29/786; G02F 1/1333; G02F 1/1368; G02F 1/1362; H01L 27/32

(52) U.S. Cl. CPC H01L 27/1255; H01L 27/124; H01L 29/78633; H01L 27/1225; H01L 27/3265; H01L 27/3262; H01L 27/3248; H01L 27/323; G02F 2001/13685; G02F 1/1368; G02F 1/13624; G02F 1/136227; G02F 1/136209; H01L 27/3272; G02F 1/13338; H01L 29/7869; H01L 29/78675

(57) ABSTRACT

A display device is disclosed, which includes: a first substrate; a first thin film transistor disposed on the first substrate; a second thin film transistor disposed on the first substrate; a first capacitance electrode; and a second capacitance electrode. The first thin film transistor includes: a first semiconductor layer comprising silicon; and a first electrode electrically connected to the first semiconductor layer. The second thin film transistor includes: a second semiconductor layer comprising metal oxide; and a second electrode electrically connected to the second semiconductor layer. The first capacitance electrode is electrically connected to the first electrode, the second capacitance electrode is electrically connected to the second electrode, and the second capacitance electrode and the first capacitance electrode overlap.

### CROSS REFERENCE TO RELATED APPLICATION

This application claims the benefits of the Chinese Patent Application Serial Number 201611089421.1, filed on Dec. 1, 2016, the subject matter of which is incorporated herein by reference.

This application claims the benefit of filing date of U. S. Provisional Application Ser. Nos. 62/337,384 and 62/358,177, respectively filed on May 17 and Jul. 5, 2016 under 35 USC §119(e)(1).

### BACKGROUND

### 1. Field

The present disclosure relates to display devices, and more particularly to a display device comprising both a low-temperature polycrystalline silicon thin film transistor (TFT) and a metal oxide thin film transistor (TFT).

### 2. Description of Related Art

With the continuous advancement of technologies related to displays, all the display panels are now developed toward compactness, thinness, and lightness. This trend makes thin displays, such as liquid crystal display panels, organic light-emitting diode display panels and inorganic light-emitting diode display panels, replace cathode-ray-tube displays as the mainstream display devices on the market. Applications of thin displays are numerous. Most electronic products for daily use, such as mobile phones, notebook computers, video cameras, still cameras, music displays, mobile navigators, and TV sets, employ such display panels.

While liquid crystal display devices and organic light-emitting diode display devices are popular on the market, in which LCD display devices particularly enjoy technical maturity, manufacturers pay even more effort to improve display devices in terms of display quality thereby answering to ongoing technical development of display devices and consumers' increasing demands.

The thin film transistor (TFT) structure can be polycrystalline silicon thin film transistors (TFT) featuring high carrier mobility, or metal oxide thin film transistors (TFT) featuring low leakage. There are presently no displays combining these two types of transistors because the processes for making the two are not quite compatible, making the overall manufacturing of display devices complicated (such as by requiring more times of chemical vapor deposition). Moreover, in a single pixel unit of the organic light-emitting diode display device, there are at least three thin film transistors (TFTs), so the light-emitting area is limited and production of the thin film transistor (TFT) substrate is complicated. In view of this, a need exists for an improved and simplified process for manufacturing a thin film transistor (TFT) substrate that has both a polycrystalline silicon thin film transistor (TFT) and a metal oxide thin film transistor (TFT).

### SUMMARY

The primary objective of the present disclosure is to disclose a display device, which has both a low-temperature polycrystalline silicon thin film transistor and a metal oxide thin film transistor at the same time.

In one aspect of the present disclosure, a display device comprises: a first substrate; a first thin film transistor disposed on the first substrate; a second thin film transistor disposed on the first substrate; a first capacitance electrode; a second capacitance electrode; and a display medium layer disposed on the first substrate. Therein, the first thin film transistor includes: a first semiconductor layer comprising silicon; and a first electrode electrically connected to the first semiconductor layer. The second thin film transistor includes: a second semiconductor layer comprising metal oxide; and a second electrode electrically connected to the second semiconductor layer. The first capacitance electrode is electrically connected to the first electrode, and the second capacitance electrode is electrically connected to the second electrode. The second capacitance electrode and the first capacitance electrode overlap.

In the foregoing aspect, with the first capacitance electrode electrically connected to the first electrode and the second capacitance electrode electrically connected to the second electrode, the thin film transistor (TFT) structure in the display device is simplified.

In another aspect of the present disclosure, a display device comprises: a first substrate; a second thin film transistor disposed on the first substrate; a third thin film transistor disposed on the first substrate; and a display medium layer disposed on the first substrate. Therein, the second thin film transistor includes: a second gate; and a second semiconductor layer overlapping with the second gate, wherein the second semiconductor layer comprises metal oxide. The third thin film transistor includes: a third gate; and a third semiconductor layer overlapping with the third gate, wherein the third semiconductor comprises metal oxide. In addition, the second semiconductor layer is electrically connected to the third semiconductor layer.

In the aspect described previously; since the second semiconductor layer and third semiconductor layer both comprise metal oxide and are electrically connected to each other, the second and third thin film transistor structures are structurally simplified.

Other objects, advantages, and novel features will become more apparent from the following detailed description when taken in conjunction with the accompanying drawings.

### BRIEF DESCRIPTION OF THE DRAWINGS

FIG. 1 is a schematic cross sectional view of a display device in accordance with Embodiement 1 of the present disclosure.

FIG. 2A and FIG. 2B are equivalent-circuit diagrams of different alternative of the first pixel of the display device according to Embodiment 1 of the present disclosure.

FIG. 3 is a schematic cross sectional view of the first pixel of the display device in accordance with Embodiement 1 of the present disclosure.

FIG. 4 is a schematic cross sectional view of the first pixel of the display device in accordance with Embodiment 2 of the present disclosure.

FIG. 5 is a cross sectional view of the first pixel of the display device in accordance with Embodiment 3 of the present disclosure.

FIG. 6 is a schematic cross sectional view of the first pixel of the display device in accordance with Embodiment 4 of the present disclosure

FIG. 7 is a schematic cross sectional view of the first pixel of the display device in accordance with Embodiment 5 of the present disclosure

FIG. 8 is a schematic cross sectional view of the first pixel of the display device in accordance with Embodiment 6 of the present disclosure

FIG. 9 is a schematic cross sectional view of the first pixel of the display device in accordance with Embodiment 7 of the present disclosure

FIG. 10 is a schematic cross sectional view of the first pixel of the display device in accordance with Embodiment 8 of the present disclosure. FIG. 11 is a schematic cross sectional view of the first pixel of the display device in accordance with Embodiment 9 of the present disclosure.

FIG. 12 is a schematic cross sectional view of the first pixel of the display device in accordance with Embodiment 10 of the present disclosure.

FIG. 13 is a schematic cross sectional view of the first pixel of the display device in accordance with Embodiment 11 of the present disclosure.

FIG. 14 is a schematic cross sectional view of the first pixel of the display device in accordance with Embodiment 12 of the present disclosure.

FIG. 15 is a schematic cross sectional view of the first pixel of the display device in accordance with Embodiment 13 of the present disclosure.

FIG. 16 is a schematic cross sectional view of the first pixel of the display device in accordance with Embodiment 14 of the present disclosure.

FIG. 17 is a schematic cross sectional view of the first pixel of the display device in accordance with Embodiment 15 of the present disclosure.

FIG. 18 is a schematic cross sectional view of the first pixel of the display device in accordance with Embodiment 16 of the present disclosure.

FIG. 19 is a schematic cross sectional view of the first pixel of the display device in accordance with Embodiment 17 of the present disclosure.

FIG. 20 is a schematic cross sectional view of the first pixel of the display device in accordance with Embodiment 18 of the present disclosure.

FIG. 21 is a schematic cross sectional view of the first pixel of the display device in accordance with Embodiment 19 of the present disclosure.

FIG. 22 is a schematic cross sectional view of the first pixel of the display device in accordance with Embodiment 20 of the present disclosure.

FIG. 23 is a schematic cross sectional view of the first pixel of the display device in accordance with Embodiment 21 of the present disclosure.

FIG. 24 is a schematic cross sectional view of the first pixel of the display device in accordance with Embodiment 22 of the present disclosure.

FIG. 25 is a schematic cross sectional view of the first pixel of the display device in accordance with Embodiment 23 of the present disclosure.

FIG. 26 is a schematic cross sectional view of the first pixel of the display device in accordance with Embodiment 24 of the present disclosure.

FIG. 27 is a schematic cross sectional view of the first pixel of the display device in accordance with. Embodiment 25 of the present disclosure.

FIG. 28 is a schematic cross sectional view of the first pixel of the display device in accordance with Embodiment 26 of the present disclosure.

FIG. 29 is a schematic cross sectional view of the first pixel of the display device in accordance with Embodiment 27 of the present disclosure.

FIG. 30 is a schematic cross sectional view of the first and second pixels of the display device in accordance with Embodiment 28 of the present disclosure.

FIG. 31 is a schematic cross sectional view of the first pixel of the display device in accordance with Embodiment 29 of the present disclosure.

FIG. 32 is a schematic cross sectional view of the first pixel of the display device in accordance with Embodiment 30 of the present disclosure.

### DETAILED DESCRIPTION OF THE EMBODIMENT

The disclosure as well as mode of uses, further objectives and advantages thereof will be best understood by reference to the following detailed description of illustrative embodiments when read in conjunction with the accompanying drawings.

In the specification and the appended claims, the ordinal numbers like “first” and “second” are just descriptive to the elements following them and do not mean or signify that the claimed elements are such numbered, that one claimed element is arranged with another claimed element in that order, and that the claimed elements are produced in that order. These ordinal numbers are only used to help differentiate one claimed element having a denomination from another claimed element having the same denomination.

Herein, the phrase “overlapping with” or “overlap” includes partially or entirely overlapping or overlap. In addition, the phrase “exposing” including partially or entirely exposing.

### Embodiment 1

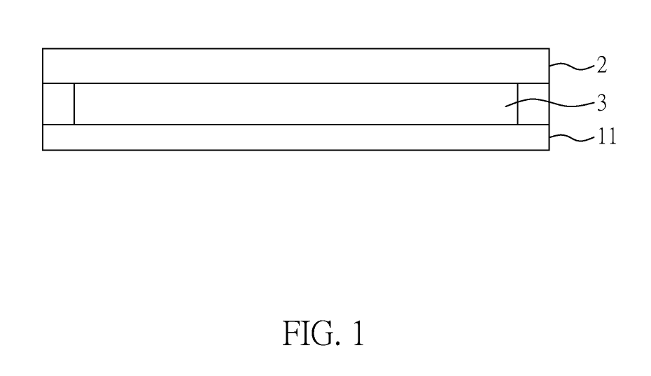

FIG. 1 is a top view and a schematic cross sectional view a display device in accordance with the present embodiment. Therein, the display device comprises: a first substrate 11; a second substrate 2 opposite to the first substrate 11; and a display medium layer 3 arranged between the first substrate 11 and the second substrate 2. In the present embodiment, the first substrate 11 and the second substrate 2 may be made of glass, plastic, a flexible material or thin film. The display medium 3 may be a liquid crystal layer, an organic light-emitting layer, a diode chip array, but not limited thereto. In the present embodiment and the following embodiments of the present disclosure, the display device is an organic light-emitting diode display device, and the display medium 3 is an organic light-emitting layer. In other embodiments of the present disclosure, the display device which is an organic light-emitting diode display device or a diode chip array display is optionally made without the second substrate 2.

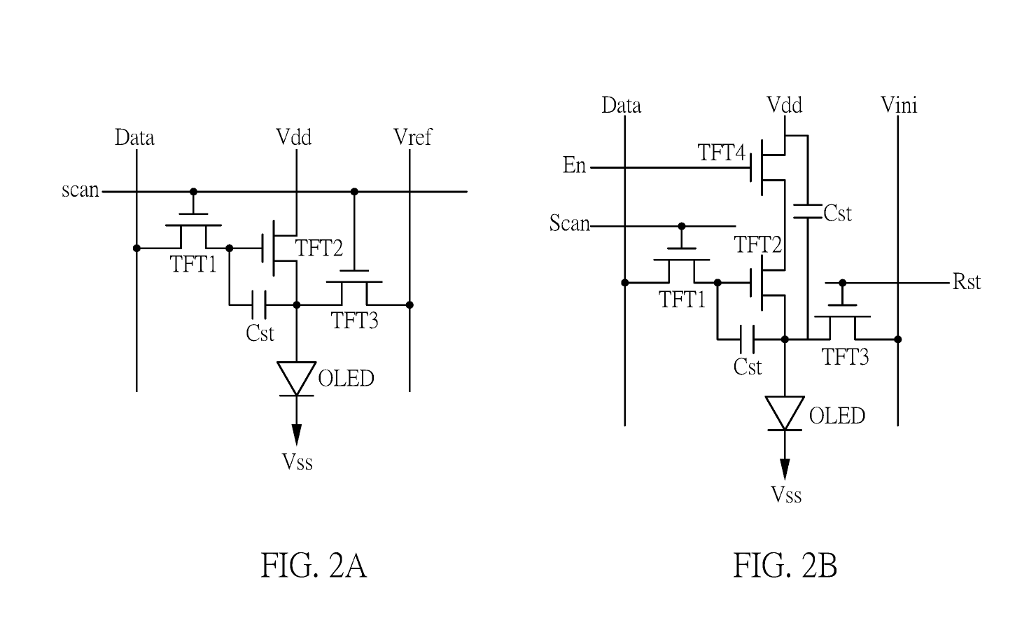

In the display device of the present embodiment, the first substrate 11 is provided with a plurality of pixel units. One of these pixel units, i.e. a first pixel unit, may be designed as, for example, the equivalent-circuit diagrams as shown in FIG. 2A and FIG. 2B. In the equivalent-circuit diagram of FIG. 2A, the first pixel includes: a first thin film transistor TFT1 acting as a switch TFT; a second thin film transistor TFT2 acting as a driving TFT; a third thin film transistor TFT3 acting as a reset TFT; and a capacitor Cst. In another equivalent-circuit diagram shown in FIG. 2B, the first pixel further comprises: a fourth thin film transistor TFT4 acting as an emitting TFT; and another capacitor Cst. In the present embodiment and the following embodiments of the present disclosure, the first thin film transistor TFT1 may be a low-temperature polycrystalline silicon thin film transistor (TFT) or a metal oxide thin film transistor (TFT). In one embodiment, the first thin film transistor TFT1 is a low-temperature polycrystalline silicon TFT. The second thin film transistor TFT2 may be a metal oxide thin film transistor for having good stability to threshold voltage (Vth). The third thin film transistor TFT3 may be a low-temperature polycrystalline silicon thin film transistor (TFT) or a metal oxide thin film transistor (TFT). The fourth thin film transistor TFT4 may be a low-temperature polycrystalline silicon thin film transistor (TFT). In the present embodiment and the following embodiments of the present disclosure, the equivalent-circuit diagram of the first pixel unit as shown in FIG. 2A will be referred to for explanation.

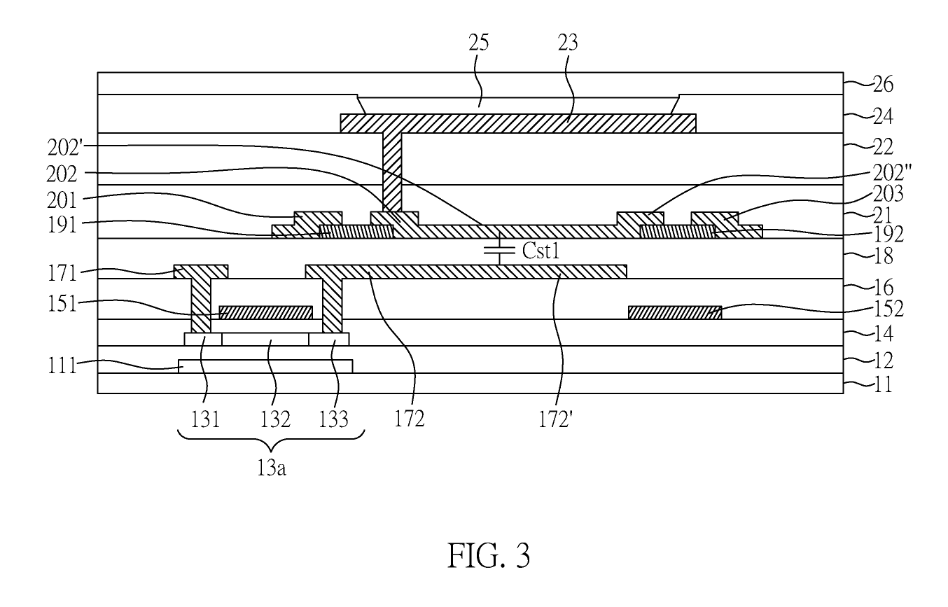

FIG. 3 is a schematic cross sectional view of the first pixel of the present embodiment. First, a first substrate 11 is prepared, and a light shielding layer 111 is formed on the first substrate 11 in the area where the first semiconductor layer 13a of the first thin film transistor (TFT) TFT1 is to be formed. Therein, light shielding layer 111 may be made of any light-shielding materials, such as metal or a black matrix. In the present embodiment, the light shielding layer 111 is made of a metal (such as molybdenum, chrome, titanium or other metal with good thermo-stability). Then, a buffer layer 12 is formed on the first substrate 11 and the light shielding layer 111. The buffer layer 12 may be made of silicon oxide or silicon nitride or may be a layered structure made of silicon nitride and silicon oxide. Afterward, a first semiconductor layer 13a is disposed on the buffer layer 12 to act as a first active layer. It is formed by using a laser crystallization process and a channel doping process to transform an amorphous silicon layer into a low-temperature polycrystalline silicon layer. Therein, the first semiconductor layer 13a includes a source area 131, a channel area 132 and a drain area 133. Then, a first gate insulating layer 14 is formed on the first semiconductor layer 13a. The first gate insulating layer 14 is made of silicon nitride, silicon oxide, or combination thereof. A first gate 151 and a third gate 152 are formed on the first gate insulating layer 14 as a single-layer or multi-layer structure made of a metal or metals, such as Cu, Ti, or Al, or metal alloy. The first gate 151 and the third gate 152 electrically connect to scanning lines (not shown). A second insulating layer 16 is formed on the first gate insulating layer 14 using silicon nitride or silicon or as a layered structure made of silicon nitride and silicon oxide. On the second insulating layer 16, a first conducting layer including a first electrode 172 and the first capacitance electrode 172′, and a third electrode 171 are formed and made of a metal or metals, such as Cu, Al, Mo, MoN, TiN, Ti or combination thereof. Thereby, the formation of the first thin film transistor TFT1 of the present embodiment (as shown in FIG. 2A) is finished.

Then, a first insulating layer 18 is formed on the first electrode 172, the first capacitance electrode 172′ and the third electrode 171. The first insulating layer is made of silicon nitride, silicon oxide or combination thereof. A second semiconductor layer 191 and a third semiconductor layer 192 are formed on the first insulating layer 18. The second semiconductor layer 191 and the third semiconductor layer 192 comprise metal oxide, which may be a zinc-oxide-based metal oxide, such as IGZO, ITZO, IGZTO, etc. In the present embodiment and the following embodiments of the present disclosure, the second semiconductor layer 191 and the third semiconductor layer 192 which respectively comprises a zinc-oxide-based metal oxide are made of IGZO. A second conducting layer including a second electrode 202, a second capacitance electrode 202′ and a fourth electrode 201 are formed on the second semiconductor layer 191 and the third semiconductor layer 192. The second conducting layer further comprises a fifth electrode 203. Therein, the second conducting layer may be formed of metal such as Cu or Al, Mo, MoN, TiN, Ti or combination thereof. Thereby, the formation of the second thin film transistor TFT2 (as shown in FIG. 2A) and the third thin film transistor TFT3 (as shown in FIG. 2A) of the present embodiment is finished. Subsequently, a planar layer 21 is formed on the second conducting layer, and an organic layer 22 is further optionally formed on the planar layer 21. At last, a first display electrode 23, a pixel defining layer 24, an organic light-emitting layer 25, and a second display electrode 26 are successively formed on the organic layer 22. The first display electrode 23, the organic light-emitting layer 25, and the second display electrode 26 form the organic light-emitting diode unit of the present embodiment. Therein, the first display electrode 23 is electrically connected to the second electrode 202 of the second thin film transistor (TFT) TFT2. Herein, the first display electrode 23 and the second display electrode 26 may each be a transparent electrode or a semi-transparent electrode. Therein, the transparent electrode may be a transparent oxide electrode (a TCO electrode), such as an ITO electrode or an IZO electrode. The semi-transparent electrode may be a metal thin film electrode, such as a magnesium-silver-alloy thin film electrode, a gold thin film electrode, a platinum thin film electrode, an aluminum thin film electrode and so on. Furthermore, if necessary, at least one of the first display electrode 23 and the second display electrode 26 may be a composite electrode of a transparent electrode and a semi-transparent electrode, such as a composite electrode of a TCO electrode and a platinum thin film electrode. Herein, while the organic light-emitting diode device having the first display electrode 23, the organic light-emitting layer 25, and the second display electrode 26 is described as an example, the present disclosure is not limited thereto. Other organic light-emitting diode devices may be used in the organic light-emitting diode display device of the present disclosure, such as an electron transport layer, an electron injection layer, a hole transport layer, a hole injection layer, and other organic light-emitting diode devices helping transport and binding of electrons and holes. All these may be used in the present disclosure.

Through the foregoing process, the organic light-emitting diode display device of the present embodiment is made. As shown in FIG. 2A and. FIG. 3, the display device of the present embodiment has one of its pixels, i.e. the first pixel including a first substrate 11; a first thin film transistor TFT1 disposed on the first substrate 11; a second thin film transistor TFT2 disposed on the first substrate 11; a first capacitance electrode 172′; a second capacitance electrode 202′; and a display medium layer (i.e. the organic light-emitting diode unit, including the first display electrode 23, the organic light-emitting layer 25 and the second display electrode 26) disposed on the first substrate 11. Therein, the first thin film transistor TFT1 includes: a first semiconductor layer 13a comprising silicon; and a first electrode 172 electrically connected to the :first semiconductor layer 13a. The second thin film transistor TFT2 includes: a second semiconductor layer 191 comprising metal oxide; and a second electrode 202 electrically connected to the second semiconductor layer 191. Moreover, in the display device of the present embodiment, the first capacitance electrode 172′ is electrically connected to first electrode 172, the second capacitance electrode 202′ is electrically connected to the second electrode 202, and the first capacitance electrode 172′ and the second capacitance electrode 202′ overlap, thereby forming a first capacitor Cst1.

As shown in FIG. 2A and. FIG. 3, in the display device of the present embodiment, the :first capacitance electrode 172′ and the first electrode 172 are integrated, while the second capacitance electrode 202′ and second electrode 202 are integrated. In addition, with the first capacitance electrode 172′ overlapping with the second capacitance electrode 202′ to form the first capacitor Cst1, the thickness of the first insulating layer 18 and in turn the size of the first capacitor Cst1 (i.e., the capacitor Cst of FIG. 2A) can be controlled.

Furthermore, as shown in FIG. 3, in the display device of the present embodiment, the first electrode 172 of the first thin film transistor TFT1 and the second semiconductor layer 191 overlap, so a part of the first electrode 172 can act as a second gate of the second thin film transistor TFT2.

As shown in FIG. 2A and FIG. 3, in the display device of the present embodiment, using a part of the first electrode 172 of the first thin film transistor TFT1 as the second gate of the second thin film transistor TFT2 not only makes the first thin film transistor TFT1 electrically connected to the second thin film transistor TFT2, but also simplifies the formation of the first thin film transistor TFT1 and the second thin film transistor TFT2, and reduces the area taken by the first thin film transistor TFT1 and the second thin film transistor TFT2 on the first substrate 11, thereby improving the aperture ratio.

Furthermore, the display device of the present embodiment further comprises a third thin film transistor TFT3 that is disposed on the first substrate 11 and includes a third semiconductor layer 192 comprising metal oxide (e.g., an IGZO layer); and a second extended electrode 202″ and a fifth electrode 203 both disposed on the third semiconductor layer 192 and electrically connected to the third semiconductor layer 192. Therein, the second extended electrode 202″ and the second capacitance electrode 202′ are integrated.

As shown in FIG. 2A and FIG. 3, in the display device of the present embodiment, the second electrode 202, the second extended electrode 202″ and the second capacitance electrode 202′ are formed in to an integral so as to act as the electrode of both the second thin film transistor TFT2 and the third thin film transistor TFT3, thereby electrically connected to each other.

### Embodiment 2

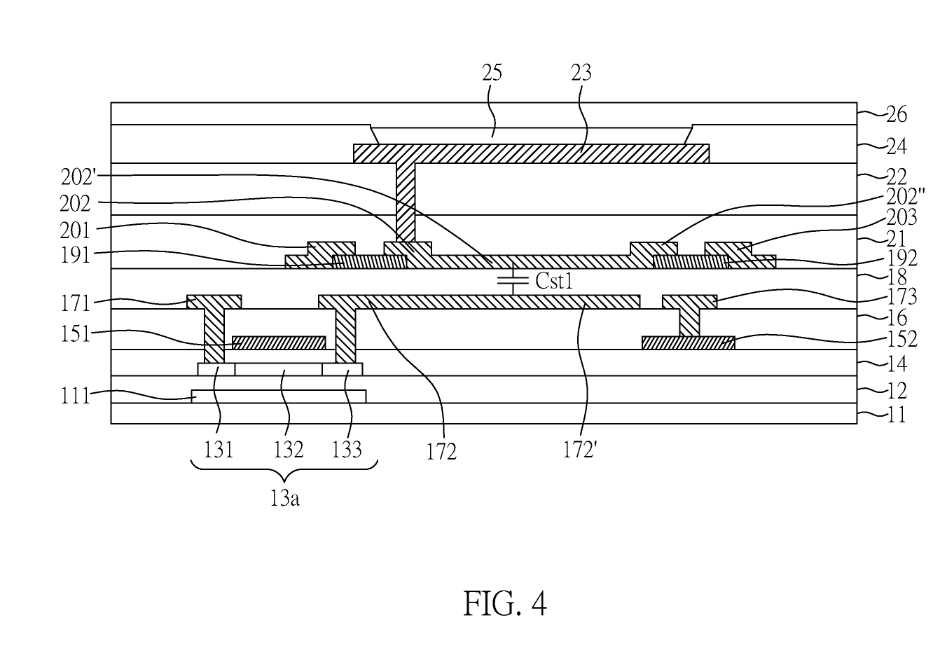

FIG. 4 is a schematic cross sectional view of the first pixel of the display device of the present embodiment. The display device of the present embodiment is similar to Embodiment 1, with the only difference that the first conducting layer (including the first electrode 172 and the first capacitance electrode 172′) on the second insulating layer 16 further comprises a connecting portion 173 electrically connected to the third gate 152. While the first electrode 172 or the first capacitance electrode 172′ of the first conducting layer on the cross-sectional view of FIG. 4 is not directly connected to the third gate 152, the first electrode 171 or the first capacitance electrode 172 may be directly connected to the connecting portion 173 in other areas of the display device, thereby achieving electrical connection between the first electrode 172 or the first extended electrode 172′ and the third gate 152. With the first thin film transistor TFT1 first electrode 172 or the first extended electrode 172′ electrically connected to the third gate 152 of the third TFT TFT3, the charging capability of the third TFT TFT3 can be further improved.

### Embodiment 3

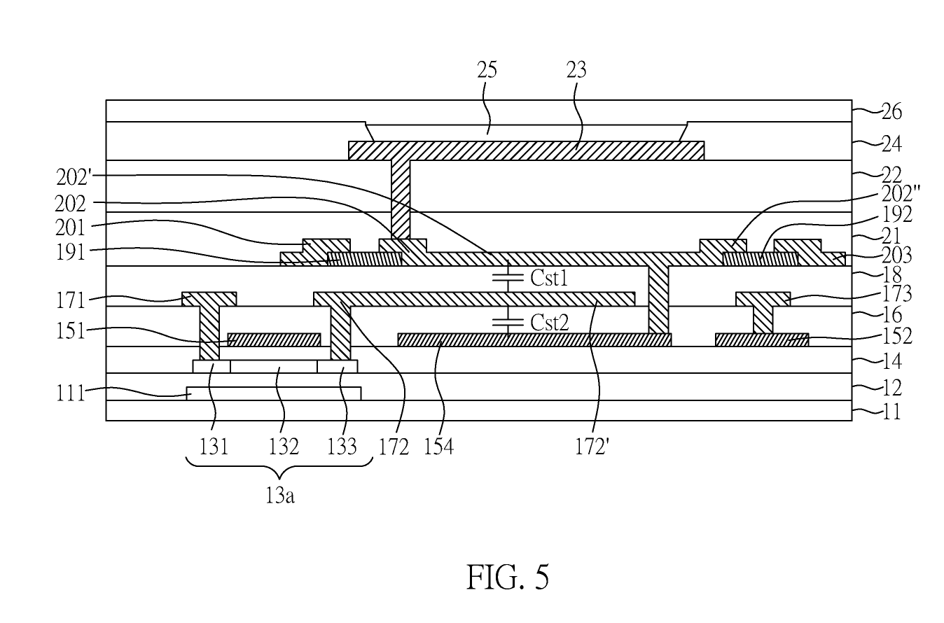

FIG. 5 is a schematic cross sectional view of the first pixel of the display device of the present embodiment. The display device of the present embodiment is similar to Embodiment 2, with the only difference that a third capacitance electrode 154 is formed at the same time as when the first gate 151 and the third gate 152 are formed. Thus, in the present embodiment, the display device further comprises a third capacitance electrode 154. Therein, the second insulating layer 16 is disposed between the third capacitance electrode 154 and the first conducting layer (including the first electrode 172 and the first capacitance electrode 172′), and the third capacitance electrode 154 and the first capacitance electrode 172′ of the first conducting layer overlap so as to form a second capacitor Cst2. Therein, the second capacitance electrode 202′ is electrically connected to the third capacitance electrode 154 by means of a through hole, so as to supply a voltage to the third capacitance electrode 154. Thus, as shown in FIG. 2A and FIG. 5, in the present embodiment, the display device further comprises a second capacitor Cst2. The second capacitor Cst2 has a third capacitance electrode 154. The first gate 151 corresponds to the first semiconductor layer 13a, and a first gate insulating layer 14 is disposed between the first gate 151 and the first semiconductor layer 13a. Therein, the third capacitance electrode 154 and the first gate 151 are directly formed on the same surface as the first gate insulating layer 14, and directly contact the surface, so that the third capacitance electrode 154 and the first gate 151 are located in the same plane. Furthermore, the third capacitance electrode 154 and the third gate 152 are directly formed on the same surface as the first gate insulating layer 14 and directly contact the surface, so that the third capacitance electrode 154 and the third gate 152 are located in the same plane.

Thus, in the present embodiment, the display device includes not only the first capacitor Cst1 formed by overlapping the first capacitance electrode 172′ with the second capacitance electrode 202′, but also the second capacitor Cst2 formed by overlapping the third capacitance electrode 154 with the first capacitance electrode 172′.

### Embodiment 4

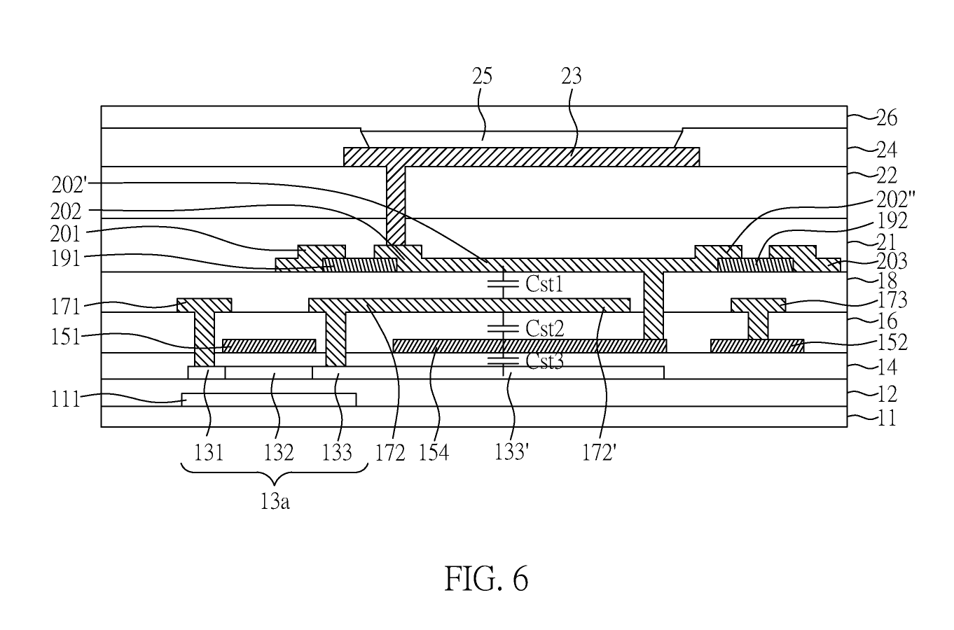

FIG. 6 is a schematic cross sectional view of the first pixel of the display device of the present embodiment. The display device of the present embodiment is similar to Embodiment 3, with the only difference that the drain area 133 of the first semiconductor layer 13a is such extended that the drain area 133 of the first semiconductor layer 13a and the third capacitance electrode 154 overlap. Thus, the extension of the drain area 133 of the first semiconductor layer 13a may act as a fourth capacitance electrode 133′. Therefore, in the display device of the present disclosure, the third insulating layer (i.e., the first gate insulating layer 14) is disposed between the third capacitance electrode 154 and the first semiconductor layer 13a. The fourth capacitance electrode 133′ formed by the extension of the drain area 133 of the first semiconductor layer 13a and the third capacitance electrode 154 overlap, so as to form a third capacitor Cst3. Thus, the display device of the present embodiment may further comprise a third capacitor Cst3. The third capacitor Cst3 includes the fourth capacitance electrode 133′, and the fourth capacitance electrode 133 and the first semiconductor layer 13a are made of an identical material and electrically connected to each other.

In the present embodiment, display device not only has the first capacitor Cst1 and the second capacitor Cst2 as described in Embodiment 3, but also has the third capacitor Cst3 formed by the overlapped third capacitance electrode 154 and fourth capacitance electrode 133′.

### Embodiment 5

FIG. 7 is a schematic cross sectional view of the first pixel of the display device of the present embodiment. The display device of the present embodiment is similar to Embodiment 1, with the only difference described below. As shown in FIG. 2A and FIG. 7, in the display device of Embodiment 1, the third thin film transistor TFT3 is a metal oxide TFT, whereas in the present embodiment, the third thin film transistor TFT3 is a low-temperature polycrystalline silicon thin film transistor (TFT). At the time of forming the light shielding layer 111, a light shielding layer 112 is also formed in an area of the third thin film transistor TFT3. At the time of forming the first semiconductor layer 13a of the first thin film transistor TFT1, the third semiconductor layer 13b of the third thin film transistor TFT3 is also formed and the third semiconductor layer 13b includes a source area 134, a channel area 135, and a drain area 136. At the time of forming the first conducting layer, a third source 174 and a third drain 175 are also formed. The third source 174 and the third drain 175 are electrically connected to the source area 134 and the drain area 136 of the third semiconductor layer 13b, respectively. Furthermore, the second capacitance electrode 202′ is also electrically connected to the third source 174 by means of the through hole.

### Embodiment 6

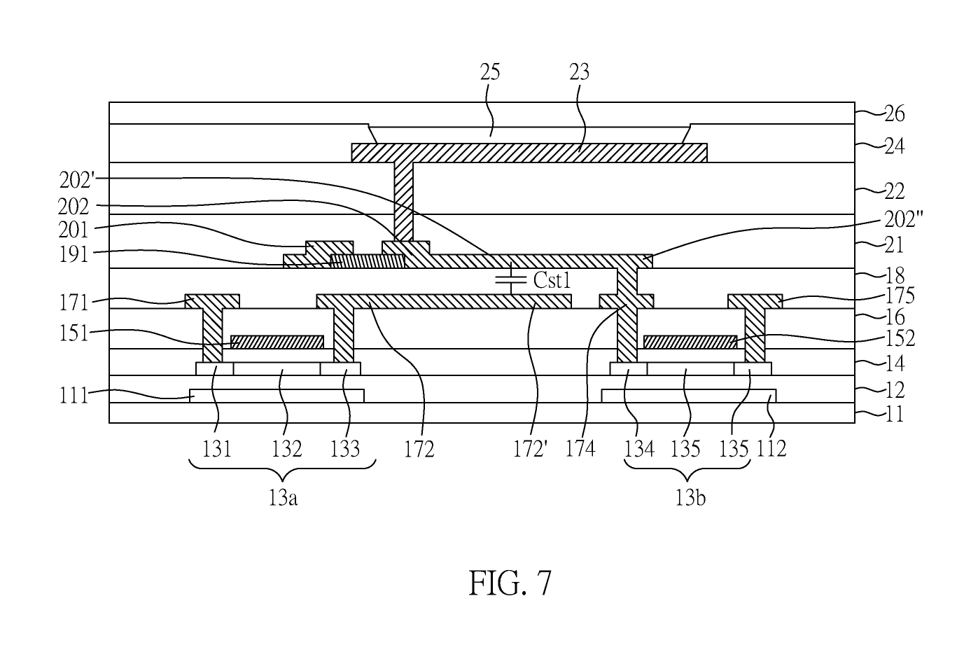

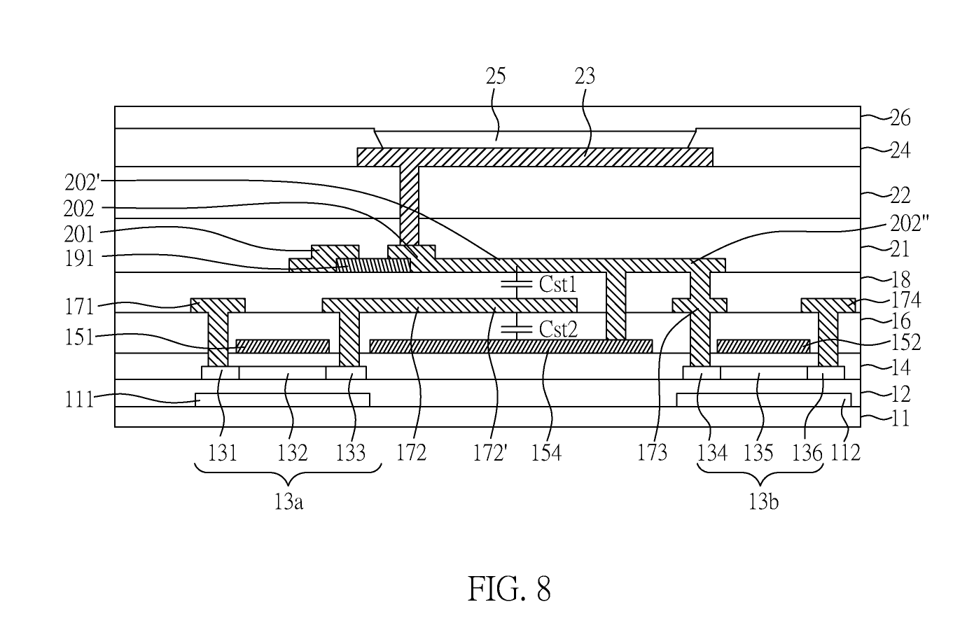

FIG. 8 is a schematic cross sectional view of the first pixel of the display device of the present embodiment. The display device of the present embodiment is similar to Embodiment 5, with the only difference that at the time of forming the first gate 151 and the third gate 152, a third capacitance electrode 154 is further formed. Therein, the second insulating layer 16 is disposed between the third capacitance electrode 154 and the first conducting layer (including the first electrode 172 and the first capacitance electrode 172′), and the third capacitance electrode 154 and the first capacitance electrode 172′ of the first conducting layer overlap so as to form a second capacitor Cst2. Therein, the second capacitance electrode 202′ is electrically connected to the third capacitance electrode 154 by means of a through hole, so as to supply a voltage to third capacitance electrode 154. The design details of the second capacitor Cst2 are similar to those of Embodiment 3, and repeated description is omitted herein.

### Embodiment 7

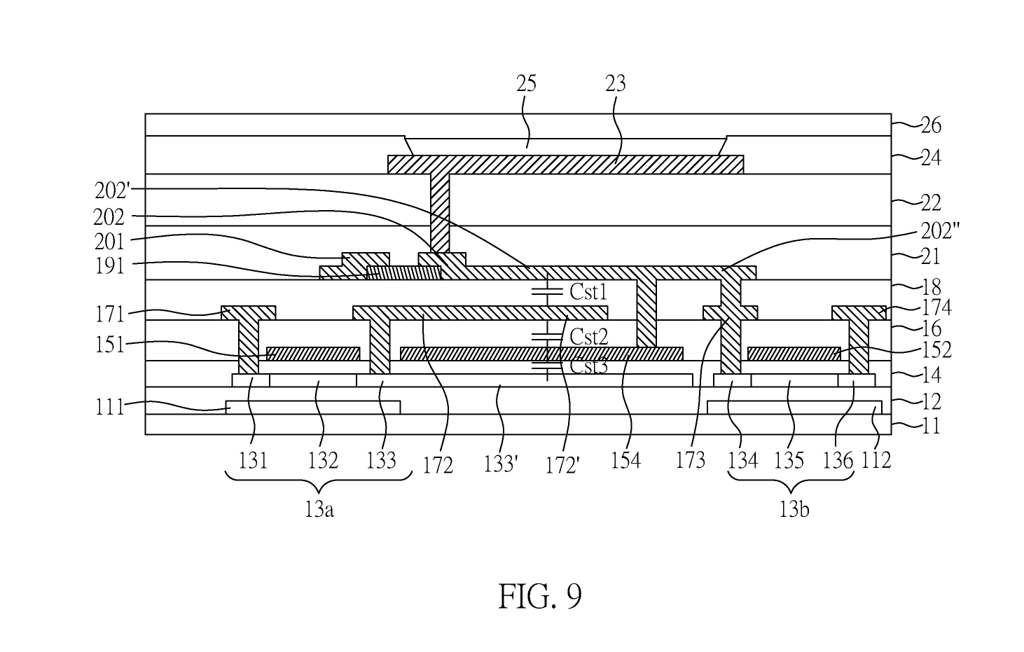

FIG. 9 is a schematic cross sectional view of the first pixel of the display device of the present embodiment. The display device of the present embodiment is similar to Embodiment 6, with the only difference that the drain area 133 of the first semiconductor layer 13a is such extended that the drain area 133 of the first semiconductor layer 13a and the third capacitance electrode 154 overlap. Thus, the extension of the drain area 133 of the first semiconductor layer 13a acts as a fourth capacitance electrode 133′. In the display device of the present disclosure, the third insulating layer (i.e., first gate insulating layer 14) is disposed between the third capacitance electrode 154 and the first semiconductor layer 13a. The fourth capacitance electrode 133′ is formed by the extension of the drain area 133 of the first semiconductor layer 13a. The fourth capacitance electrode 133′ and the third capacitance electrode 154 overlap so as to form a third capacitor Cst3. The design details of the third capacitor Cst3 are similar to those of Embodiment 3, and repeated description is omitted herein.

### Embodiment 8

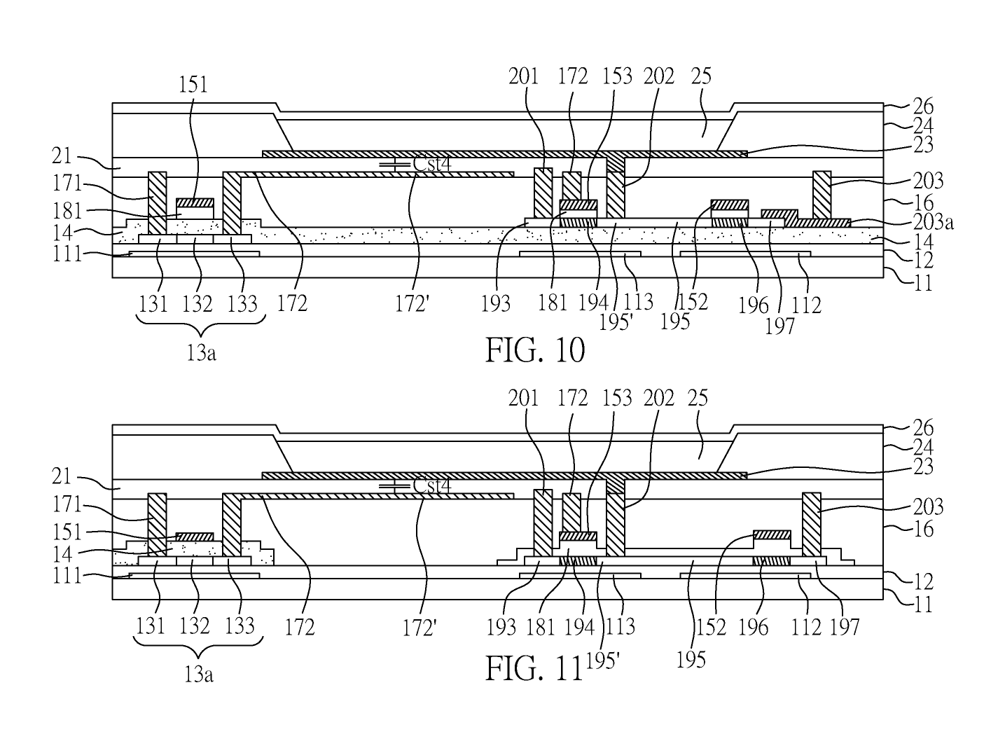

FIG. 10 is a schematic cross sectional view of the first pixel of the display device of the present embodiment. The first pixel of the present embodiment has its equivalent-circuit diagram similar to that shown in FIG. 2A, and repeated description is omitted herein.

As shown in FIG. 2A and FIG. 10, first, a first substrate 11 is prepared, and light shielding layers 111, 112, 113 are formed in an area on the first substrate 11 where an active layer of the thin film transistor (TFT) is formed. Then, a buffer layer 12 is formed on the first substrate 11 and the light shielding layers 111, 112, 113. Afterward, a first semiconductor layer 13a is disposed on the buffer layer 12, as a low-temperature polycrystalline silicon layer that comprises a source area 131, a channel area 132 and a drain area 133. Then, a first gate insulating layer 14 is formed on the first semiconductor layer 13a. In an area of the first gate insulating layer 14 where the second thin film transistor TFT2 and the third thin film transistor TFT3 are formed, a second semiconductor layer comprises a metal oxide layer including a second source area 193, a second active area 194, a second drain area 195; and a third semiconductor layer is formed and comprises a metal oxide layer including a third source area 195′, a third active area 196, and a third drain area 197. Therein, the second semiconductor layer and the third semiconductor layer are integrated. Subsequently, in the channel area 132 of the first semiconductor layer 13a, the second active area 194, and the third active area 196,a second gate insulating layer 181 (made of silicon oxide) and a first gate 151, a second gate 153, and a third gate 152 successively. Then a second insulating layer 16 is formed on the first gate 151, the second gate 153 and the third gate 151. The second insulating layer is made of silicon nitride. Afterward, a third electrode 171 electrically connected to the source area 131 of the first semiconductor layer 13a and a first electrode 172 electrically connected to the drain area 133 are formed. What are formed now are a second electrode 201 electrically connected to the second source area 193, a second electrode 202 electrically connected to the second drain area 195 and the third source area 195′, and a fifth electrode 203 electrically connected to the third drain area 197. In the present embodiment, a connecting electrode 203a is further formed between the third drain area 197 and the fifth electrode 203. However, this connecting electrode 203a is optional. In other embodiments of the present disclosure, the display device may be made with or without the connecting electrode 203a, depending on its design. Through the forgoing process, the formation of the first TFT TFT1, the second TFT TFT2, and the third TFT TFT3 of the present embodiment is finished.

At last, a planar layer 21 is formed on the third electrode 171, the first electrode 172, the first capacitance electrode 172′, the fourth electrode 201, the second electrode 202, and the fifth electrode 203. A first display electrode 23, a pixel defining layer 24, an organic light-emitting layer 25, and a second display electrode 26 are then successively formed so as to form the organic light-emitting diode unit of the present embodiment. Therein the first display electrode 23 is electrically connected to the second electrode 202 of the second thin film. transistor (TFT) TFT2.

Through the forgoing process, the formation of the organic light-emitting diode display device of the present embodiment is finished. As shown in FIG. 2A and FIG. 10, the display device of the present embodiment includes; a first substrate 11; a second thin film transistor TFT2 disposed on the first substrate 11; a third thin film transistor TFT3 disposed on the first substrate 11; and a display medium layer including a first display electrode 23, an organic light-emitting layer 25, and a second display electrode 26, and disposed on the first substrate 11. Therein, the second thin film transistor TFT2 includes: a second gate 153; and a second semiconductor layer (including a second source area 193, a second active area 194 and a second drain area 195). The second active area 194 of the second semiconductor layer and the second gate 153 overlap, wherein the second semiconductor layer comprises metal oxide. The third thin film transistor TFT3 includes: a third gate 152; and a third semiconductor layer (including a third source area 195′, a third active area 196, and a third drain area 197). The third active area 196 of the third semiconductor layer and the third gate 152 overlap, wherein the third semiconductor layer comprises metal oxide. The second semiconductor layer and the third semiconductor layer are integrated and thereby electrically connect to each other. Furthermore, the display device of the present embodiment further comprises: a light shielding layer 111 disposed between the first semiconductor layer 13a and the first substrate 11 and overlapping with the first semiconductor layer 13a; and light shielding layers 112, 113, overlapping with the second semiconductor layer that comprises the second active area 194 and the third active area 196, respectively.

As shown in FIG. 2A and FIG. 10, in the display device of the present embodiment, the second semiconductor layer (including the second source area 193, the second active area 194, and the second drain area 195) and the third semiconductor layer (including the third source area 195′, the third active area 196, and the third drain area 197) are integrated. Because hydrogen is diffused from the second insulating layer 16 which is made of silicon nitride to the second source area 193, the second drain area 195, the third source area 195′ and the third drain area 197. Therefore, the electrical conductivity of the second source area 193, the second drain area 195, the third source area 195′ and the third drain area 197 is improved.

Herein, while in the cross-sectional view of FIG. 10, the first capacitance electrode 172′ is not directly connected to the second gate 153, the first capacitance electrode 172′ may in other areas of the display device be directly connected to the second gate 153, thereby achieving electrical connection between the first thin film transistor TFT1 and the second thin film transistor TFT2.

Furthermore, in the display device of the present embodiment, the display medium layer includes an organic light-emitting diode unit, which at least has a :first display electrode 23, an organic light-emitting layer 25, and a second display electrode 26. Therein, the organic light-emitting diode unit is disposed above the second thin film transistor TFT2 and electrically connected to the second thin film transistor TFT2. More particularly, it is electrically connected to the second drain and the second extended electrode 202 in the third source area 195.

Moreover, the display device of the present embodiment further comprises a first thin film transistor TFT1 and a planar layer 21. Therein, the first thin film transistor TFT1 is disposed on the first substrate 11 and includes: a first semiconductor layer 13a comprising silicon; and a first electrode 172 electrically connected to the first semiconductor layer 13. Furthermore, the planar layer 21 is disposed between the first conducting layer and the organic light-emitting diode unit, and the first capacitance electrode 172′ of the first conducting layer and the first display electrode 23 of the organic light-emitting diode unit overlap so as to form a fourth capacitor Cst4.

### Embodiment 9

FIG. 11 is a schematic cross sectional view of the first pixel of the display device of the present embodiment. The display device of the present embodiment is similar to Embodiment 8, with the only difference described below. In the present embodiment, the second gate insulating layer 181 is not disposed in the channel area 132 of the first semiconductor layer 13a. The first gate insulating layer 14 is only disposed in the first TFT area, Furthermore, the second gate insulating layer 181 is not disposed only in the second active area 194 and the third active area 196, but also in a part of the second source area 193, the second drain area 195, the third source area 195′, and the third drain area 197. In other words, the second gate insulating layer 181 almost cover the entire metal oxide layer except the areas of the metal oxide layer for connecting to the third electrode 201, the second electrode 202, and the fifth electrode 203. Furthermore, a thickness of the second gate insulating layer 181 is thin on the second source area 193, the second drain area 195, the third source area 195′, and the third drain area 197, and a thickness of the second gate insulating layer 181 is thick on the second active area 194 and the third active area 196. Moreover, there is not a connecting electrode 203a between the third drain area 197 and the fifth electrode 203.

### Embodiment 10

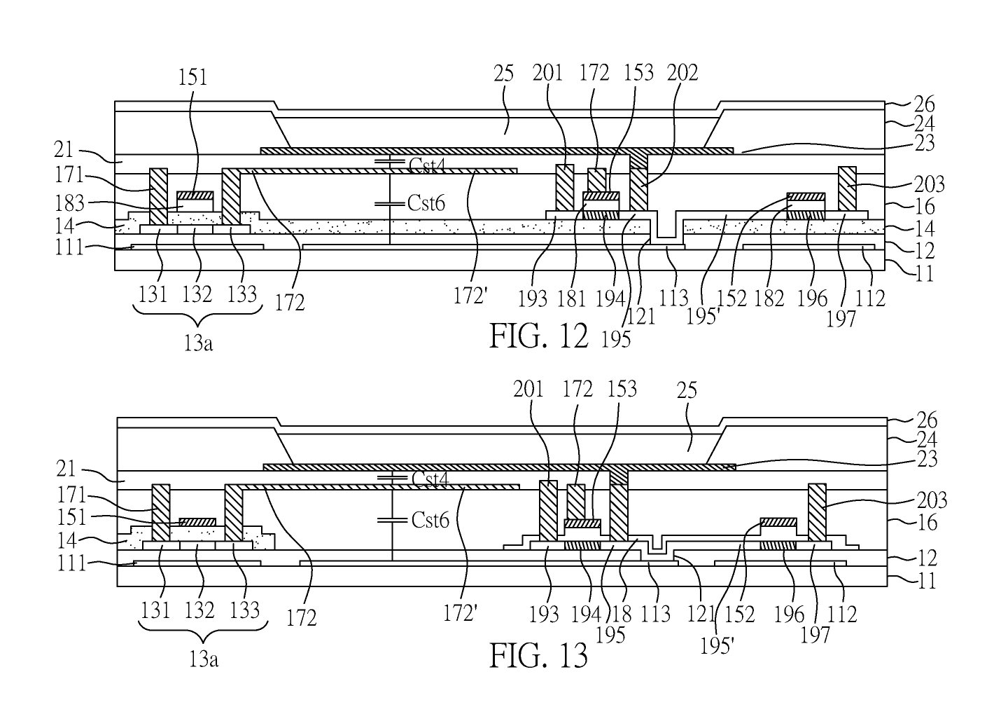

FIG. 12 is a schematic cross sectional view of the first pixel of the display device of the present embodiment. The display device of the present embodiment is similar to Embodiment 8, with the only difference described below. In the present embodiment, the light shielding layer 113 is disposed in the area where the second thin film transistor is to be formed. The light shielding layer 113 and the first capacitance electrode 172′ of the first conducting layer overlap. Since the light shielding layer 113 is made of metal, it can act as a fifth capacitance electrode. A sixth capacitor Cst6 is formed of the first capacitance electrode 172′ and the fifth capacitance electrode. Herein, the buffer layer 12 formed between the second drain area 195 and the third source area 195′ of the light shielding layer 113 and the metal oxide layer further has a contact hole 121. The second drain area 195 and the third source area 195′ are electrically connected to the light shielding layer 113 through the contact hole 121 so as to supply a voltage to the light shielding layer 113. Thus, the display device of the present embodiment further comprises a buffer layer 12 disposed between the light shielding layer 113 and the second semiconductor layer (having the second source area 193, the second active area 194, and the second drain area 195) as wells as the third semiconductor layer (having the third source area 195′, the third active area 196, and the third drain area 197). The buffer layer 12 has a contact hole 121, and the second drain area 195 of the second semiconductor layer and the third source area 195′ of the third semiconductor layer electrically connect to the light shielding layer 113 through the contact hole 121.

### Embodiment 11

FIG. 13 is a schematic cross sectional view of the first pixel of the display device of the present embodiment. The display device of the present embodiment is similar to Embodiment 9, with the only difference described below. In the present embodiment, the light shielding layer 113 is disposed in the area where the second thin film transistor is to be formed, and the light shielding layer 113 and the first capacitance electrode 172′ of the first conducting layer overlap. Since the light shielding layer 113 is formed of metal, it can work with the first capacitance electrode 172′ to form a sixth capacitor Cst6. Herein, a buffer layer 12 disposed between the light shielding layer 113 an the second drain area 195 and the third source area 195′ of the metal oxide layer further has a contact hole 121. The second drain area 195 and the third source area 195′ electrically connect to the light shielding layer 113 through the contact hole 121 so as to supply a voltage to the light shielding layer 113.

### Embodiment 12

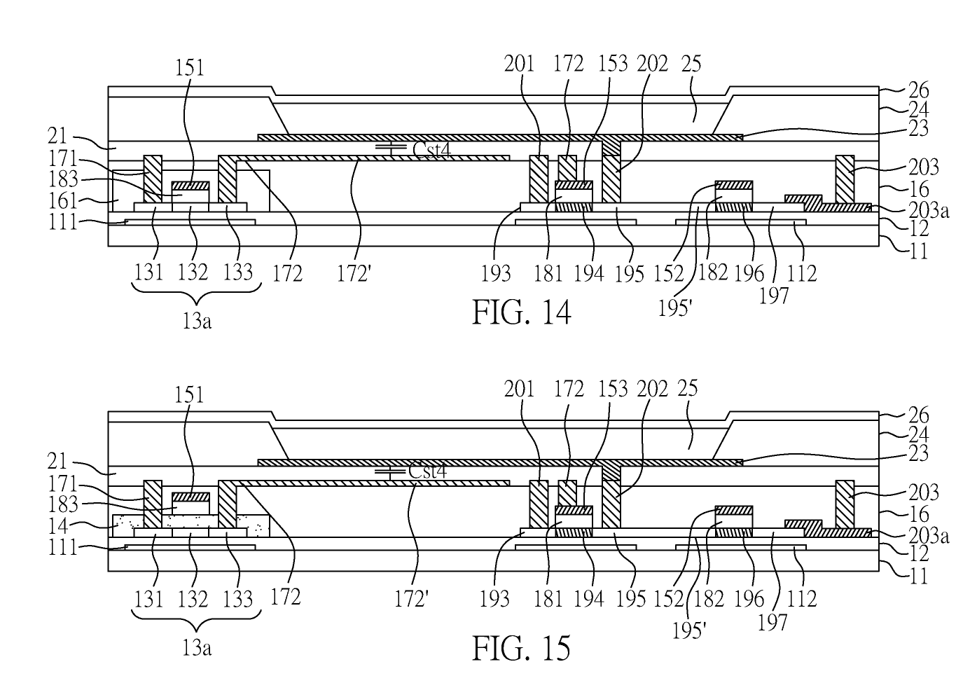

FIG. 14 is a schematic cross sectional view of the first pixel of the display device of the present embodiment. The display device of the present embodiment is similar to Embodiment 8, with the only difference that in the first thin film transistor area, after a first gate 151 is formed, a fourth insulating layer 161 is formed before the second insulating layer 16 and other layers are subsequently formed in a way similar to that of Embodiment 8. Herein, fourth insulating layer 161 is made of silicon oxide.

### Embodiement 13

FIG. 15 is a schematic cross sectional view of the first pixel of the display device of the present embodiment. The display device of the present embodiment is similar to Embodiment 8, but the first gate insulating layer 14 is only disposed in first TFT area.

### Embodiement 14

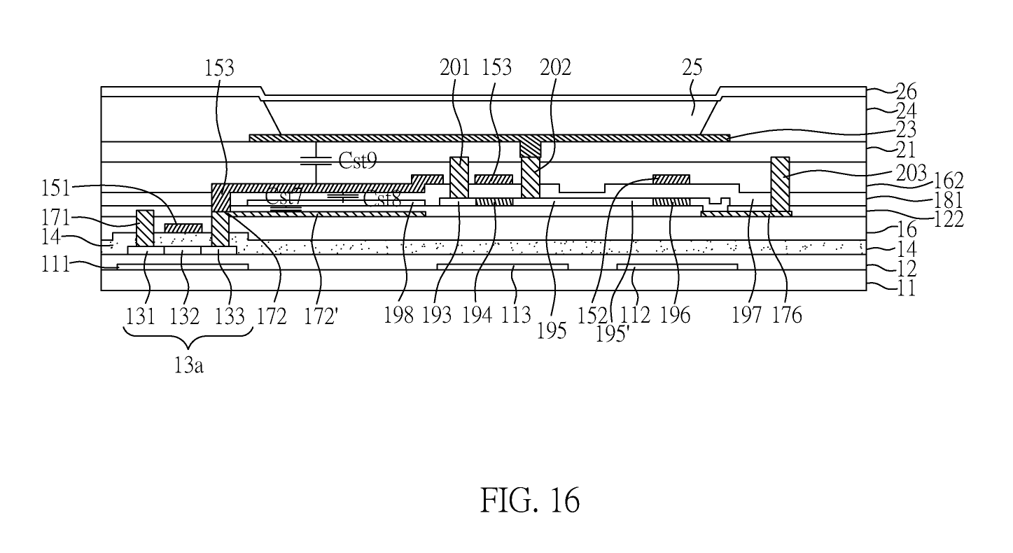

FIG. 16 is a schematic cross sectional view of the first pixel of the display device of the present embodiment. The display device of the first thin film transistor of the present embodiment is made in a way similar to that associated with Embodiment 8, and repeated description is omitted herein. The main difference between the present embodiment and Embodiment 8 is the formation of the second and the third thin film transistors.

As shown in FIG. 16, after the third electrode 171, the first electrode 172, and the first capacitance electrode 172′ are formed, a buffer layer 122 is further formed. A second semiconductor layer including a second source area 193, a second active area 194, and a second drain area 195 is formed on the buffer layer 122, and a third semiconductor layer including a third source area 195′, a third active area 196, and a third drain area 197 is formed on the buffer layer 122. A second gate insulating layer 181 is formed on the second semiconductor layer and the third semiconductor layer. Afterward, a second gate 153 and a third gate 152 are formed on the second gate insulating layer 181. Then, a fifth insulating layer 162 is formed on the second gate 153 and the third gate 152, before a fourth electrode 201, a second electrode 202, and a fifth electrode 203 are formed, thereby finishing the formation of the second and the third TFT. At last, after the planar layer 21 is formed, an organic light-emitting diode unit is made using a process similar to that of the Embodiment 8, therey finishing the formation of the organic light-emitting diode display device of the present embodiment.

In the present embodiment, at the time of forming the second semiconductor layer and the third semiconductor layer, a capacitor electrode 198 is also formed. The capacitor electrode 198 and the first capacitance electrode 172′ of the first conducting layer overlap so as to form a seventh capacitor. Cst7 with the first capacitance electrode 172′. Furthermore, the second gate 153 is electrically connected to the first electrode 172, and the second gate 153 and the capacitor electrode 198 overlap so as to form an eight capacitor Cst8. Herein, while the second gate 153 in the cross-sectional view shown in FIG. 16 is discontinuous and inserted therein with a fourth electrode 201, in other areas of the display device of the present embodiment, the second gate 153 is continuous and electrically connected to the first electrode 172, thereby making the first thin film transistor TFT1 and the second thin film transistor TFT2 electrically connected to each other. Moreover, a nith capacitor Cst9 can be formed of the second gate 153 and the first display electrode 23 of the organic light-emitting diode unit.

### Embodiement 15

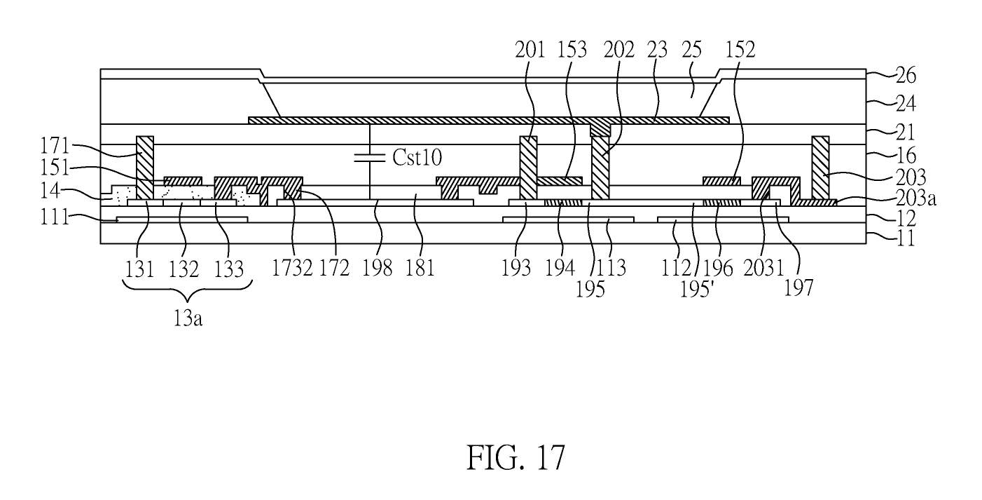

FIG. 17 is a schematic cross sectional view of the first pixel of the display device of the present embodiment. The display device of the present embodiment is similar to Embodiment 9, with the only difference described below. In the present embodiment, the metal oxide layer further comprises a capacitor electrode 198, and the second gate insulating layer 181 is further disposed in the capacitor electrode 198. Furthermore, the first capacitance electrode 172′and the second gate 153 of the first conducting layer are electrically connected to each other through the capacitor electrode 198. Herein, the planar layer 21 and the second insulating layer 16 are disposed between the capacitor electrode 198 and the first display electrode 23 of the organic light-emitting diode unit, and the capacitor electrode 198 and the first display electrode 23 overlap so as to form a tenth capacitor Cst10.

### Embodiement 16

FIG. 18 is a schematic cross sectional view of the first pixel of the display device of the present embodiment. The display device of the first thin film transistor of the present embodiment is made in a way similar to that associated with Embodiment 1, and repeated description is omitted herein. The main difference between the present embodiment and Embodiement 1 is the formation of the second and the third thin film transistors.

In the present embodiment, the second and third TFTs are designed similarly to Embodiment 8, and the second source area 193, the second active area 194 and the second drain area 195 of the second thin film transistor and the third source area 195′, the third active area 196, and the third drain area 197 of the third thin film transistor are formed of a single metal oxide layer. In other words, the display device of the present embodiment further comprises a third thin film transistor TFT3 (as shown in FIG. 2A), wherein the third thin film transistor TFT3 comprises a third semiconductor layer including a third source area 195′, a third active area 196, and a third drain area 197. The second semiconductor layer (including the second source area 193, the second active area 194, and the second drain area 19) and the third semiconductor layer(including the third source area 195′, the third active area 196, and the third drain area 197) both comprise metal oxide and are electrically connected to each other. Therein, the second source area 193 is provided with a fourth electrode 201 of the second conducting layer, and the third drain area 197 is provided with a fifth electrode 203.

Furthermore, the planar layer 21 further comprises an aperture 211 to expose the second drain area 195 and the third source area 195′. A sixth insulating layer 221 is formed on the planar layer 21 and in its aperture 211. Herein, the planar layer 21 is made of silicon oxide, and the sixth insulating layer 221 is made of silicon nitride. Herein, the planar layer 21 is also an insulating layer which is located on the second semiconductor layer and the third semiconductor layer. The planar layer 21 (i.e. the insulating layer) has a first part (without the aperture 211) and a second part (with the aperture 211). The first part has a thickness greater than that of the second part. Furthermore, the sixth insulating layer 221 contacts the second drain area 195 and the third source area 195′ so as to increase the hydrogen content in the second drain area 195 and the third source area 195′, and enhance electrical conductivity thereof.

Similar to Embodiment 1, in the display device of the present embodiment, the first capacitance electrode 172′ and the second drain area 195 overlap and the first capacitance electrode 172′ and the third source area 195′ (which can be regarded as the second capacitance electrode of the second thin film transistor) also overlap; and thus a first capacitor Cst1 is formed.

### Embodiement 17

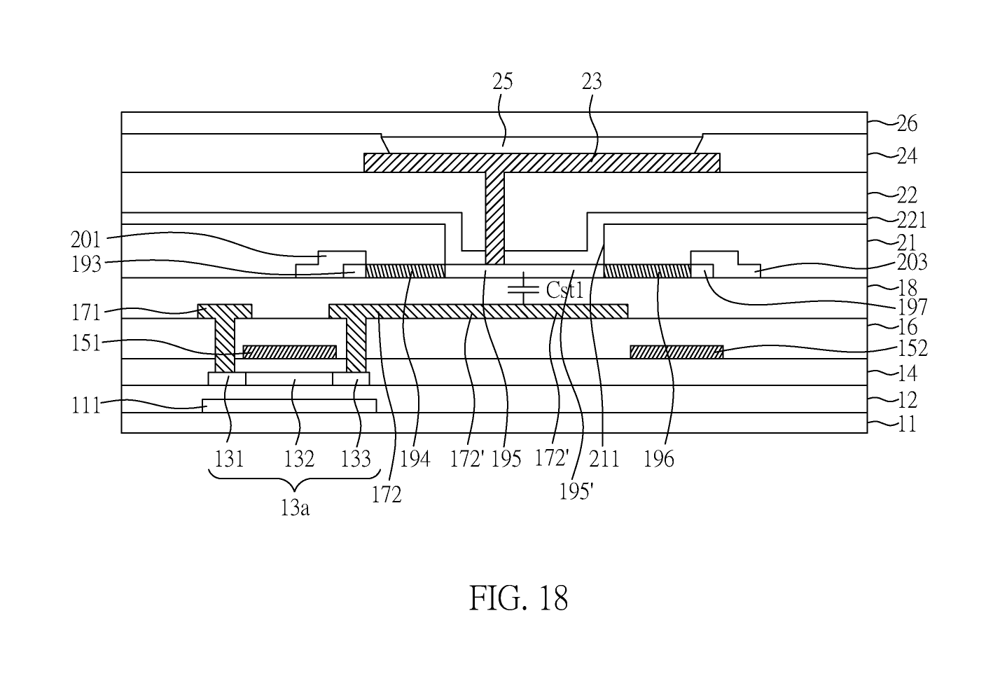

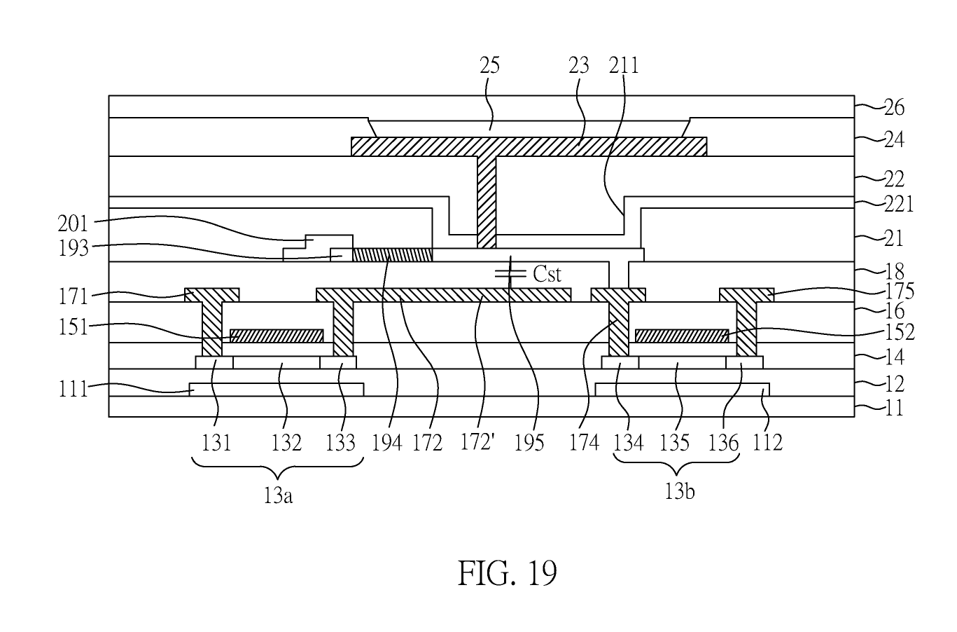

FIG. 19 is a schematic cross sectional view of the first pixel of the display device of the present embodiment. The display device of the first TFT of the present embodiment is made in a way similar to that associated with Embodiment 5, and repeated description is omitted herein. The main difference between the present embodiment and Embodiment 5 relies on the formation of the second TFT.

In the present embodiment, the second thin film transistor is designed similarly to Embodiment 8, and the second source area 193, the second active area 194, and the second drain area 195 of the second thin film transistor are formed of a single metal oxide layer. Thus, the second thin film transistor can use the second drain area 195 as the second electrode 202 and the second capacitance electrode 202′ of Embodiment 5 (as shown in FIG. 7). In the present embodiment, the planar layer 21 further comprises an aperture 211 so as to expose the second drain area 195. Moreover, a sixth insulating layer 221 is formed on the planar layer 21 and in its aperture 211. Herein, the planar layer 21 is made of silicon oxide, and the sixth insulating layer 221 is made of silicon nitride. The sixth insulating layer contacts the second drain area 195, so as to increase the hydrogen content in the second drain area 195, and enhance its electrical conductivity.

### Embodiement 18

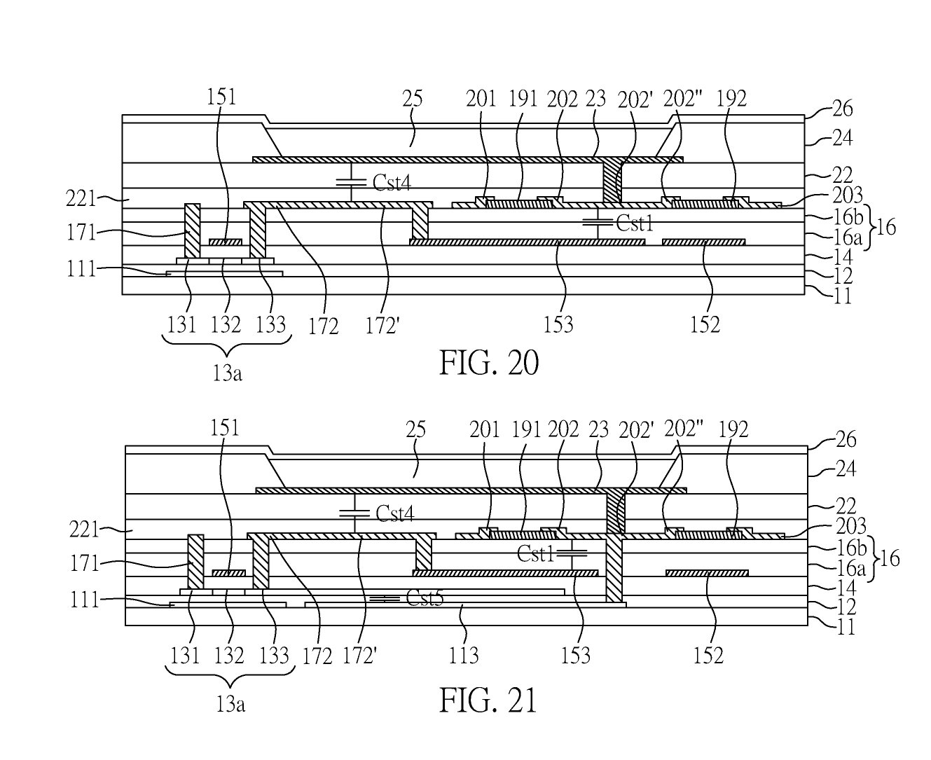

FIG. 20 is a schematic cross sectional view of the first pixel of the display device of the present embodiment. The first pixel of the present embodiment has its equivalent-circuit diagram similar to that shown in FIG. 2A, and repeated description is omitted herein.

As shown in FIG. 2A and FIG. 20, first, a :first substrate 11 is prepared, and a light shielding layer 111 is formed in an area on the first substrate 11 where an active layer of the thin film transistor (TFT) is to be formed. Then, a buffer layer 12 is formed on the first substrate 11 and the light shielding layer 111. Afterward, a first semiconductor layer 13a is disposed on the buffer layer 12, as a low-temperature polycrystalline silicon layer that comprises a source area 131, a channel area 132 and a drain area 133. Then, a first gate insulating layer 14 is formed on the first semiconductor layer 13a, before a first gate 151, a second gate 153 and a third gate 152 are formed on the first gate insulating layer 14. Subsequently, a second insulating layer 16 is formed on the first gate 151, the second gate 153 and the third gate 152. Therein, the second insulating layer 16 includes a lower second insulating layer 16a and an upper second insulating layer 16b. After a third electrode 171, a first electrode 172, and a first capacitance electrode 172′ are formed on the second insulating layer 16, the formation of the first thin film transistor of the present embodiment is finished.

Furthermore, a second semiconductor layer 191 and a third semiconductor layer 192 are formed on the second insulating layer 16. The second insulating layer 16, for example, is made of a zinc-oxide-based metal oxide, such as IGZO, ITZO, IGZTO, etc. Subsequently, a second conducting layer including a fourth electrode 201, a second electrode 202 and a second capacitance electrode 202′ is formed on the second semiconductor layer 191 and the third semiconductor layer 192, and the second conducting layer further comprises a second extended electrode 202″ and a fifth electrode 203. Then, a sixth insulating layer 221 and a planar layer 21 are formed on the second conducting layer successively. At last, the organic light-emitting diode unit of the present embodiment is formed in the way described in Embodiment 1, thereby finishing the formation of the display device of the present embodiment.

In the present embodiment, the first electrode 172 is electrically connected to the second gate 153. Thus, in the present embodiment, the second gate 153 and the second capacitance electrode 202′ overlap so as to form a first capacitor Cst1. Furthermore, the first capacitance electrode 172′ of the first conducting layer and the first display electrode 23 of the organic light-emitting diode unit overlap so as to form a fourth capacitor Cst4. Moreover, the second conducting layer can act not only an electrode of the second thin film transistor, but also an electrode of the third thin film transistor.

### Embodiement 19

FIG. 21 is a schematic cross sectional view of the first pixel of the display device of the present embodiment. The display device of the present embodiment is similar to Embodiement 18, with the only difference as described below In the present embodiment, the first substrate 11 is further provided with a light shielding layer 113 made of metal. The drain area 133 of the first semiconductor layer 13a is further extended so that the drain area 133 of the first semiconductor layer 13a and the third capacitance electrode 154 overlap. By means of the through hole, the second capacitance electrode 202′ is electrically connected to the light shielding layer 113, so that the second capacitance electrode 202′ supplies a voltage to the light shielding layer 113. Thereby, the extension of the drain area 133 of the first semiconductor layer 13a and the light shielding layer 113 form a fifth capacitor Cst5. Herein, the first semiconductor layer 13a is designed similarly to Embodiment 4 and FIG. 6, and repeated description is omitted herein.

### Embodiment 20

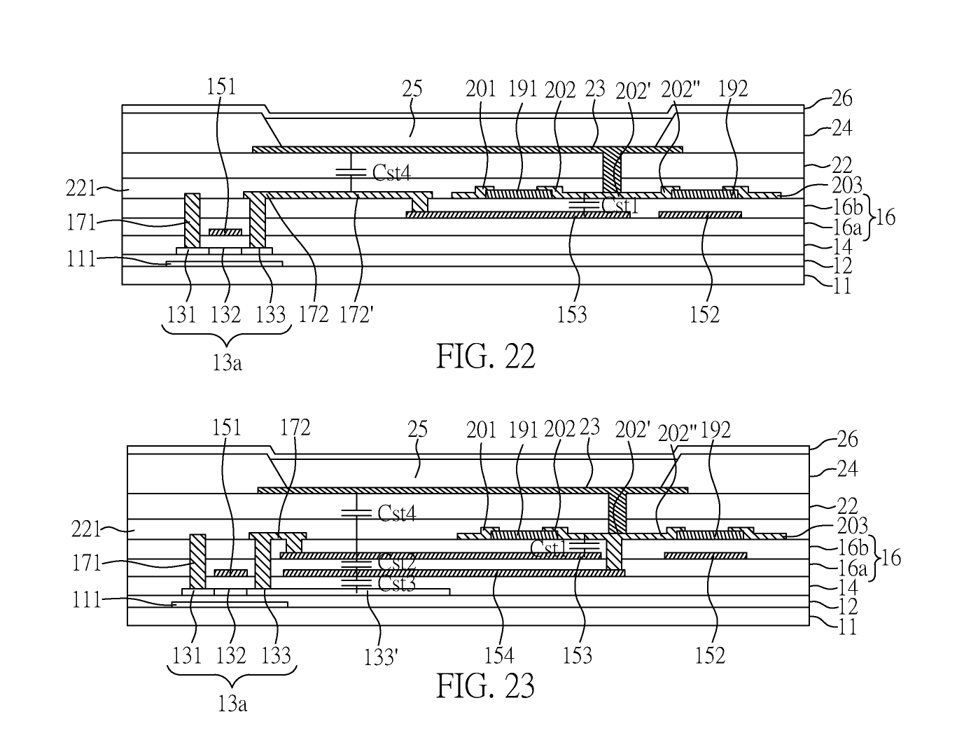

FIG. 22 is a schematic cross sectional view of the first pixel of the display device of the present embodiment. The display device of the present embodiment is similar to Embodiement 18, with the only difference that second gate 153 and the third gate 152 are positioned otherwise. In the present embodiment, the second gate 153 and the third gate 152 are disposed between the lower second insulating layer 16a and the upper second insulating layer 16b.

### Embodiment 21

FIG. 23 is a schematic cross sectional view of the first pixel of the display device of the present embodiment. The display device of the present embodiment is similar to Embodiment 20, with the only difference as described below. In the present embodiment, a third capacitance electrode 154 is further formed at the time of forming the first gate 151. Therein, by means of the through hole, the second capacitance electrode 202′ and the third capacitance electrode 154 are electrically connected to each other, so that the second capacitance electrode 202′ supplies a voltage to the third capacitance electrode 154. Thus, the second gate 153 and the third capacitance electrode 154 form a second capacitor Cst2. Therein, the third capacitance electrode 154 is designed similarly to Embodiment 3 and FIG. 5, and repeated description is omitted herein.

Furthermore, the drain area 133 of the first semiconductor layer 13a is further extended so that the drain area 133 of the first semiconductor layer 13a and the third capacitance electrode 154 overlap at its extended area. In this manner, the extension of the drain area 133 of the first semiconductor layer 13a can be a fourth capacitance electrode 133′. The fourth capacitance electrode and third capacitance electrode 154 form a third capacitor Cst3. Therein, fourth capacitance electrode 133′ is designed similarly to Embodiment 4 and FIG. 6, and repeated description is omitted herein. Moreover, in the present embodiment, the second gate 153 is not overlap with the first extended electrode 172, and the second gate 153 may overlap with the first display electrode 23 of the organic light-emitting diode unit so as to form a fourth capacitor Cst4.

### Embodiment 22

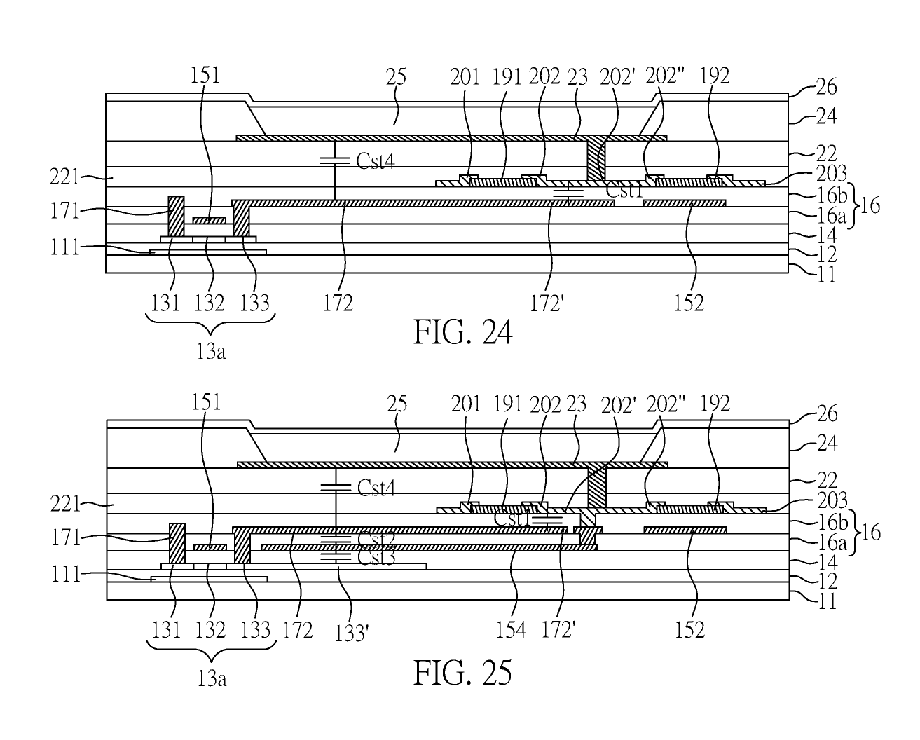

FIG. 24 is a schematic cross sectional view of the first pixel of the display device of the present embodiment. The display device of the present embodiment is similar to Embodiment 20, with the only difference as described below. In the present embodiment, after the lower second insulating layer 16a is formed, the third electrode 171, the first electrode 172 and the first capacitance electrode 172′ of the first thin film transistor are formed, and then the upper second insulating layer 16b is formed. The first capacitance electrode 172′ positionally corresponds to the second semiconductor layer 191 of the second thin film transistor, so a part of the first capacitance electrode 172′ can be the second gate of the second thin film transistor.

### Embodiment 23

FIG. 25 is a schematic cross sectional view of the first pixel of the display device of the present embodiment. The display device of the present embodiment is similar to Embodiment 22, with the only difference that a third capacitance electrode 154 is formed at the time the first gate 151 is formed. By means of the through hole, the second capacitance electrode 202′ is electrically connected to the third capacitance electrode 154, so that the second capacitance electrode 202′ supplies a voltage to the third capacitance electrode 154. Thereby, the first capacitance electrode 172′ (also acting as the second gate of the second TFT) and the third capacitance electrode 154 form a second capacitor Cst2. Therein, the third capacitance electrode 154 is designed similarly to that associated with Embodiment 3 and FIG. 5, and repeated description is omitted herein.

Furthermore, the drain area 133 of the first semiconductor layer 13a is further extended so that the drain area 133 of the first semiconductor layer 13a and the third capacitance electrode 154 overlap. In this manner, the extension of the drain area 133 of the first semiconductor layer 13a can be a fourth capacitance electrode 133′. The fourth capacitance electrode 133′ and the third capacitance electrode 154 form a third capacitor Cst3. Thus, the third capacitor Cst3 includes a fourth capacitance electrode 133′. The fourth capacitance electrode 133′ and the first semiconductor layer 13a are formed of the same material and are electrically connected to each other. Therein, the fourth capacitance electrode 133′ is designed similarly to Embodiment 4 and FIG. 6, and repeated description is omitted herein. Furthermore, the display device of the present embodiment further comprises a first capacitor Cst1. The first capacitor Cst1 has a first capacitance electrode 172′ and a second capacitance electrode 202′. The first capacitance electrode 172′ and the first semiconductor layer 13a are electrically connected to each other, while the second capacitance electrode 202′ is electrically connected to the second semiconductor layer 191 and the third semiconductor layer 192.

In the present disclosure, the display device formed according to any of the foregoing embodiments may be come with a touch-sensing panel as a touch-sensing display device. In the following description, Embodiments 24 through 30 will be directed to possible aspects of the touch-sensing display device of the present disclosure.

### Embodiment 24

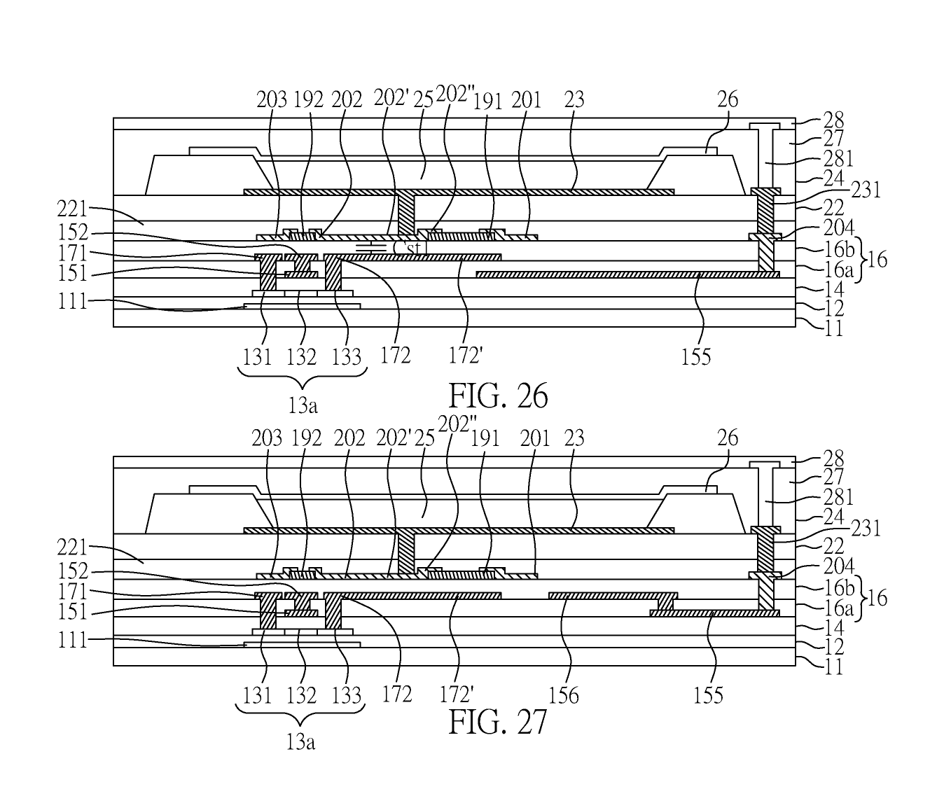

FIG. 26 is a schematic cross sectional view of the first pixel of the display device of the present embodiment. The equivalent-circuit diagram of the first pixel of the present embodiment is the same as that shown in FIG. 2A, and repeated description is omitted herein.

As shown in FIG. 2A and FIG. 26, first, a first substrate 11 is prepared, and a light shielding layer 111 is formed in an area on the first substrate 11 where the thin film transistor active layer is to be formed. Then, a buffer layer 12 is formed on the first substrate 11 and the light shielding layer 111. Afterward, a first semiconductor layer 13a is disposed on the buffer layer 12, as a low-temperature polycrystalline silicon layer that comprises a source area 131, a channel area 132 and a drain area 133. Then, a first gate insulating layer 14 is formed on the first semiconductor layer 13a, before a first gate 151 and a first touch-sensing signal line 155 are formed on the first gate insulating layer 14. Subsequently, a lower second insulating layer 16a is formed, and the third electrode 171, the first electrode 172, the first capacitance electrode 172′ and the third gate 152 are formed on the lower second insulating layer 16a. Thereby, formation of the first TFT of the present embodiment is finished.

Then, an upper second insulating layer 16b is formed on the third electrode 171, the first electrode 172, the first capacitance electrode 172′ and the third gate 152, before a second semiconductor layer 191 and a third semiconductor layer 192 are formed on the upper second insulating layer 16b. The second semiconductor layer is made of metal oxide, for example, a zinc-oxide-based metal oxide, such as IGZO, ITZO, IGZTO, etc. Subsequently; a second conducting layer that comprises a fourth electrode 201, a second electrode 202 and a second capacitance electrode 202′ is formed on the second semiconductor layer 191 and the third semiconductor layer 192, and the second conducting layer further comprises a second extended electrode 202″ and a fifth electrode 203. Then, a sixth insulating layer 221 and a planar layer 21 are formed on the second conducting layer successively. At last, the organic light-emitting diode unit of the present embodiment is formed in the way described in Embodiment 1, thereby finishing the formation of the display device of the present embodiment.

As shown in FIG. 2A and FIG. 26, in the present embodiment, the third gate 152 is electrically connected to the first gate 151, so that the :first thin film transistor and the third TFT are electrically connected to each other. Furthermore, the second thin film transistor TFT2 and the third thin film transistor TFT3 are connected to each other through the second electrode 202, the second capacitance electrode 202′ and the second extended electrode 202″. Additionally, the first capacitance electrode 172′ and the second capacitance electrode 202′ overlap to form the first capacitor Cst1.

As shown in FIG. 26, after the formation of the organic light-emitting diode unit is finished, a package layer 27 is further formed on the organic light-emitting diode unit, and a touch electrode 28 is formed on the package layer 27. Thereby, the formation of the touch-sensing display device of the present embodiment is finished. Therein, the touch electrode 28 can be electrically connected to the first touch-sensing signal line 155 by means of the through holes 204, 231, 281. The through hole 281 may be filled with metal or conductive ink in order to provide conductivity between the touch electrode 28 and the first touch-sensing signal line 155.

Thus, different from the foregoing embodiments, the display device of the present embodiment is a touch-sensing display device that further comprises a touch electrode 28 and a touch-sensing signal line (i.e., the first touch-sensing signal line 155). The touch electrode 28 is arranged above the display medium (i.e., organic light-emitting diode unit), and the touch-sensing signal line (i.e., the first touch-sensing signal line 155) is arranged between the display medium layer and the touch-sensing signal line (i.e., the first touch-sensing signal line 155), while the touch electrode 28 is electrically connected to the touch-sensing signal line (i.e., the first touch-sensing signal line 155) by means of the through holes 204, 231, 281.

### Embodiment 25

FIG. 27 is a schematic cross sectional view of the first pixel of the display device of the present embodiment. The display device of the present embodiment is similar to Embodiment 24, with the only difference that a second touch-sensing signal line 156 is further formed when the third electrode 171, the first electrode 172, the first capacitance electrode 172′ and the third gate 152 are formed, and electrically connected to the first touch-sensing signal line 155 by means of the through hole. Thus, the second touch-sensing signal line 156 and the first conducting layer that comprises the third electrode 171, the first electrode 172, the first capacitance electrode 172′ and the third gate 152 are made of the same material.

### Embodiment 26

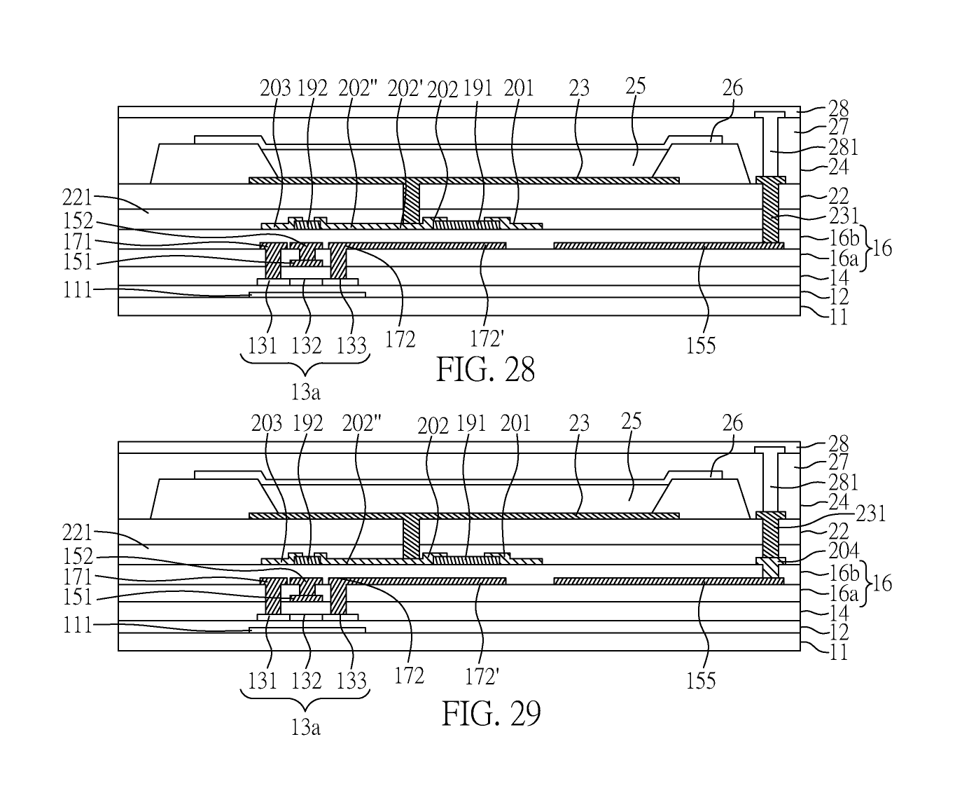

FIG. 28 is a schematic cross sectional view of the first pixel of the display device of the present embodiment. The display device of the present embodiment is similar to Embodiment 24, with the only differences that the first touch-sensing signal line 155 is formed together with the third electrode 171, the first electrode 172, the first capacitance electrode 172′ and the third gate 152, and that the touch-sensing display device does not include the through hole 204 (as shown in FIG. 26). Thus, the first touch-sensing signal line 155 and the first conducting layer that comprises the third electrode 171, the first electrode 172, the first capacitance electrode 172′ and the third gate 152 are made of the same material.

### Embodiment 27

FIG. 29 is a schematic cross sectional view of the first pixel of the display device of the present embodiment. The display device of the present embodiment is similar to Embodiment 24, with the only difference as described below. In the present embodiment, the first touch-sensing signal line 155 is formed together with the third electrode 171, the first electrode 172, the first capacitance electrode 172′ and the third gate 152. Therefore, the first touch-sensing signal line 155 and the first conducting layer that comprises the third electrode 171, the first electrode 172, the first capacitance electrode 172′ and the third gate 152 are made of the same material. Furthermore, in the present embodiment, the second semiconductor layer 191 and the third semiconductor layer 192 are integrated to form the same metal oxide layer.

### Embodiment 28

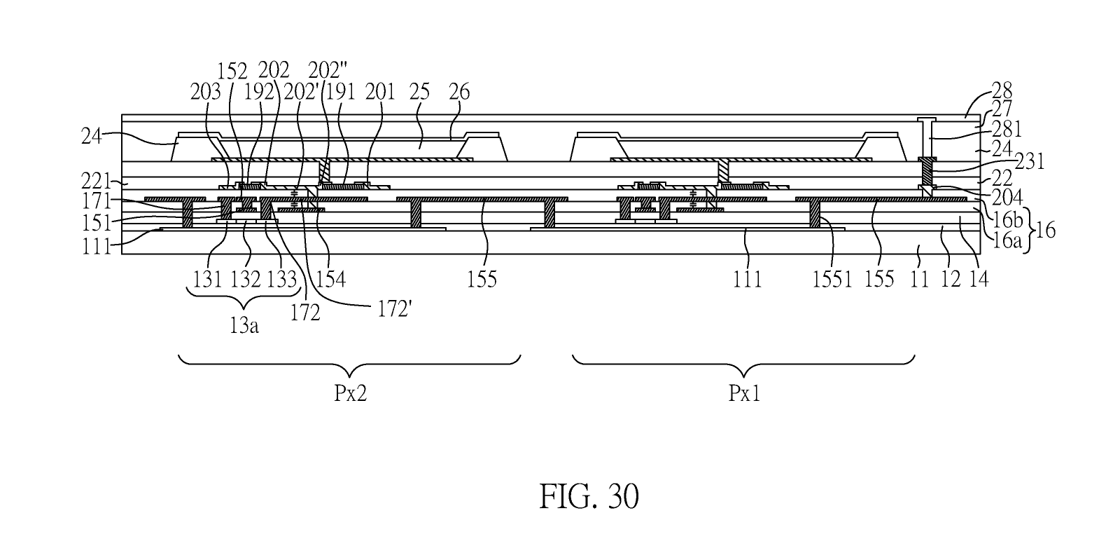

FIG. 30 is a schematic cross sectional view of the first and second pixel of the display device of the present embodiment. The display device of the present embodiment is similar to Embodiment 27, with the only difference as described below.

In the present embodiment, at the time of forming the first gate 151, the third capacitance electrode 154 is formed, and the third capacitance electrode 154 and the first capacitance electrode 172′ overlap, thereby forming a capacitor. Furthermore, in the present embodiment, the light shielding layer 111 is a metal layer, and is electrically connected to the first touch-sensing signal line 155 through at least one through hole 1551.

Moreover, the display device of the present embodiment further comprises a second pixel Px2 in addition to the first pixel Px1. The second pixel Px2 has its TFT elements structurally similar to those of the first pixel. Px1, and repeated description is omitted herein. In the present embodiment, the second pixel Px2 and the first pixel Px1 are adjacent to each other, and the light shielding layer 111 of the first pixel Px1 is electrically connected to the light shielding layer 111. of the second pixel. Px2. More specifically, the light shielding layer 111 of the first pixel Px1 is electrically connected to the light shielding layer 111 of the second pixel Px2 through the first touch-sensing signal line 155. Besides, the light shielding layer 111 is between the first semiconductor layer 13a and the first substrate 11 and the light shielding layer 111 can also be the touch-sensing signal line.

### Embodiment 29

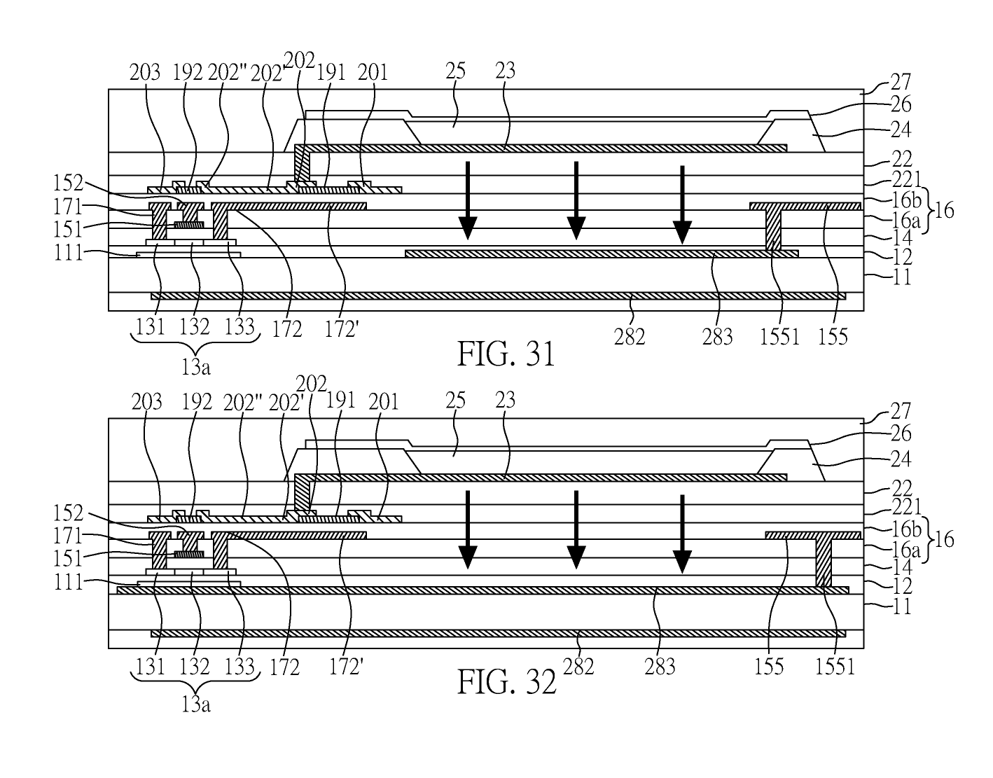

FIG. 31 is a schematic cross sectional view of the first pixel of the display device of the present embodiment. The display device of the present embodiment is similar to Embodiment 24, with the only difference described below. In the present embodiment, the organic light-emitting diode unit is a bottom-emission organic light-emitting diode unit, so the organic light-emitting layer 25 of the organic light-emitting diode does not overlap with the first, second and third thin film transistors. Therefore, in the present embodiment, the touch electrode (including the driving touch electrode 283 and the sensing touch electrode 282) is disposed on the first substrate 11. More particularly, the driving touch electrode 283 and the sensing touch electrode 282 are disposed at two sides of the first substrate 11. Additionally, the first touch-sensing signal line 155 arranged between the organic light-emitting diode unit and the first substrate 11 is further electrically connected to the driving touch electrode 283 and the sensing touch electrode 282 by means of the through hole 1551.

### Embodiment 30

FIG. 32 is a schematic cross sectional view of the first pixel of the display device of the present embodiment. The display device of the present embodiment is similar to Embodiment 29, but the light shielding layer 111 is not directly disposed on the first substrate 11. Instead, it is disposed on the driving touch electrode 283.

The display device or touch-sensing display device made in accordance with any of the embodiments of the present disclosure may be applied to any electronic devices known in the art that use a display screen. to display images, such as displays, mobile phones, notebooks, video cameras, still cameras, music displays, mobile navigators, and TV sets.

The present disclosure has been described with reference to the above embodiments and it is understood that the embodiments are not intended to limit the scope of the present disclosure. Moreover, as the contents disclosed herein should be readily understood and can be implemented by a person skilled in the art, all equivalent changes or modifications which do not depart from the concept of the present disclosure should be encompassed by the appended claims.

What is claimed is:

1. A display device, comprising:
a first substrate;
a first thin film transistor disposed on the first substrate and comprising:
a first semiconductor layer comprising silicon; and
a first electrode electrically connected to the first semiconductor layer;
a second thin film transistor disposed on the first substrate and comprising:
a second semiconductor layer comprising metal oxide; and
a second electrode electrically connected to the second semiconductor layer;
a first capacitance electrode electrically connected to the first electrode;
a second capacitance electrode electrically connected to the second electrode and overlapping with the first capacitance electrode; and
a display medium layer disposed on the :first substrate.

2. The display device of claim 1, wherein the first capacitance electrode and the first electrode are integrated, and the second capacitance electrode and the second electrode are integrated.

3. The display device of claim 1, wherein the first electrode and the second semiconductor layer overlap.

4. The display device of claim 1, further comprising a third capacitance electrode, wherein the third capacitance electrode and the first capacitance electrode overlap.

5. The display device of claim 4, wherein the third capacitance electrode electrically connected to the second capacitance electrode.

6. The display device of claim 1, further comprising a fourth capacitance electrode electrically connected to the first semiconductor layer.

7. The display device of claim 1, further comprising a touch electrode and a touch-sensing signal line electrically connected to the touch electrode, wherein the touch-sensing signal line is between the first semiconductor layer and the first substrate.

8. The display device of claim 1, further comprising a touch electrode and a touch-sensing signal line electrically connected to the touch electrode, wherein the touch-sensing signal line and the first electrode are made of the same material.

9. The display device of claim 1, further comprising a third thin film transistor, wherein the third thin film transistor comprises a third semiconductor layer and the third semiconductor layer comprises metal oxide.

10. The display device of claim 1, further comprising a third thin film transistor, wherein the third thin film transistor comprises a third semiconductor layer and the third semiconductor layer comprises silicon,

11. A display device, comprising:
a first substrate;
a second thin film transistor disposed on the first substrate and comprising:
a second gate; and
a second semiconductor layer overlapping with the second gate, wherein the second semiconductor layer comprises metal oxide;
a third thin film transistor disposed on the first substrate and comprising:
a third gate; and
a third semiconductor layer overlapping with the third gate,
wherein the third semiconductor layer comprises metal oxide; and
a display medium layer disposed on the first substrate;
wherein the second semiconductor layer electrically connected to the third semiconductor layer.

12. The display device of claim 11, wherein the second. semiconductor layer and the third semiconductor layer are connected.

13. The display device of claim 11, further comprising a first thin film transistor disposed on the first substrate, wherein the first thin film transistor comprises a first semiconductor layer and a first electrode electrically connected to the first semiconductor layer, and the first semiconductor layer comprises silicon.

14. The display device of claim 13, further comprising a light shielding layer disposed between the first semiconductor layer and the first substrate, wherein the light shielding layer and the second semiconductor layer overlap.

15. The display device of claim 14, further comprising a buffer layer disposed between the light shielding layer and the second semiconductor layer, wherein the buffer layer has a contact hole through which the second semiconductor layer electrically connected to the light shielding layer.

16. The display device of claim 13, further comprising a touch electrode and a touch-sensing signal line electrically connected to the touch electrode, wherein the touch-sensing signal line and the first electrode are made of the same material.

17. The display device of claim 13, further comprising a first capacitance electrode and a second capacitance electrode, wherein the first capacitance electrode electrically connected to the first semiconductor layer, and the second capacitance electrode electrically connected to the second semiconductor layer.

18. The display device of claim 17, further comprising a third capacitance electrode, wherein the third capacitance electrode and the first capacitance electrode overlap.

19. The display device of claim 11, further comprising a touch electrode and a touch-sensing signal line electrically connected to the touch electrode, wherein, the touch-sensing signal line is between the first semiconductor layer and the first substrate.
